(19) United States
(12) Patent Application Publication
(10) Pub. No.: US 2025/0028871 A1
(43) Pub. Date: Jan. 23, 2025

(54) METHODS, SYSTEMS, AND COMPUTER READABLE MEDIA FOR GENERATING STRUCTURAL FORMS USING MACHINE LEARNING

(71) Applicant: The Trustees of the University of Pennsylvania, Philadelphia, PA (US)

(72) Inventors: Masoud Akbarzadeh, Philadelphia, PA (US); Hao Zheng, Philadelphia, PA (US)

(21) Appl. No.: 18/765,902

(22) Filed: Jul. 8, 2024

Related U.S. Application Data
(60) Provisional application No. 63/525,641, filed on Jul. 7, 2023.

(51) Int. Cl. G06F 30/15; G06F 30/27

(52) U.S. Cl. CPC G06F 30/15; G06F 30/27

(57) ABSTRACT

A method for generating a structural form using a machine learning model includes receiving a definition of a boundary of a target structure. The method further includes generating an output force diagram using the boundary and one or more machine-learning models trained on at least one force diagram of an internal network of a natural structure. The method further includes generating a structural form within the boundary using the output force diagram.

### PRIORITY CLAIM

This application claims the priority benefit of U.S. Provisional Patent Application Ser. No. 63/525,641 filed Jul. 7, 2023, the disclosure of which is incorporated herein by reference in its entirety.

### GOVERNMENT INTEREST

This invention was made with government support under 1944691 awarded by the National Science Foundation. The government has certain rights in the invention.

### TECHNICAL FIELD

The subject matter described herein relates generally to methods, systems, and computer readable media for generating structures using machine learning, e.g., based on natural structures and using graphic statics.

### BACKGROUND

The field of graphic statics focuses on the development of geometric methods to facilitate and seek optimal solutions for structural design. The field of graphic statics includes methods of solving problems in statics. By using the corresponding geometric constructions, graphic statics can determine forces, bending moments, centers of gravity, and moments of inertia of plane figures. The methods of graphic statics can be applied in solving problems of dynamics. Graphic statics is used in structural mechanics to calculate beams, girders, and other constructions as well as to calculate the stresses in various components of mechanisms and machines. Typically, the methods of graphic statics include the construction of reciprocal form and force diagrams that can be used as a basis for form finding tools.

### SUMMARY

The subject matter described herein relates to the use of a geometry-based equilibrium method known as graphic statics and machine learning techniques to relate the morphology of structural networks, such as the structural network of a dragonfly wing, to the static equilibrium of forces for further regeneration of the network. This approach can generate similar networks with no prior information related to the topology or geometry of the network just by receiving the boundary geometry of the structure, such as the dragonfly wing. Although the dragonfly wing is presented herein as a non-limiting example, the subject matter described herein can be used to generate force diagrams and structural forms within boundaries of other structures using a boundary definition as input to a trained machine learning model.

The internal network of the dragonfly wing can be assumed as a compression/tension-only structure on a 2D plane. Consequently, another geometric diagram called the force diagram is constructed from the network by using the reciprocal diagrams of graphic statics. A new geometry of the wing is reconstructed from the force diagram with its members sized according to the force magnitude. Both form and force diagrams are used to train machine learning models for the generation of the structural network of the wing from a boundary geometry only. Neural networks can be used to generate structural patterns of multiple other species having networks with convex polygons to show the further application of the method. The methods and systems described herein can be used for generating systems learned from natural structures for use in many engineering and scientific applications.

The subject matter described herein may be implemented in hardware, software, firmware, or any combination thereof. As such, the terms “function” or “node” as used herein refer to hardware, which may also include software and/or firmware components, for implementing the feature(s) being described. In some exemplary implementations, the subject matter described herein may be implemented using a computer readable medium having stored thereon computer executable instructions that when executed by the processor of a computer control the computer to perform steps. Exemplary computer readable media suitable for implementing the subject matter described herein include non-transitory computer readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The subject matter described herein will now be explained with reference to the accompanying drawings of which:

FIG. 1 shows the force and form of the internal structure of the dragonfly wings: part A shows the form of the entire wing; part B shows the internal form diagram containing vertexes (v), edges (e), and faces (ƒ); part C shows an internal force diagram containing vertexes (v^{†}), edges (e^{†}), and faces (ƒ^{†}); and part D the correspondence of the dual diagram. FIG. 1, part B, is a flow chart of geometric method. FIG. 1, part C, illustrates the Minkowski sum of the dragonfly wing geometry;

FIG. 2 is a force diagram of a dragonfly wing;

FIG. 3, part A, is a flow chart showing the predication and analysis of the thicknesses of dragonfly wing members. FIG. 3, part B, shows an example of comparison of a generated dragonfly wing structure to a real dragonfly wing;

FIG. 4, parts A and B, shows the workflow of machine learning models used to generate the structural form of a dragonfly wing;

FIG. 5 illustrates a comparison of the real and the generated dragonfly wings in the three categories;

FIG. 6A shows the visualization of the circularity measure on the wing polygons;

FIG. 6B shows the visualization of the area measure on the wing polygons;

FIG. 7, part A, illustrates plots of the area and the circularity of each polygon for the real wing and the generated wings. FIG. 7, part B, shows the smooth curve of the area and the circularity of each polygon for the real wing and the generated wing;

FIGS. 8A and 8B illustrate the use of the methodology described herein to design an airplane wing;

FIG. 9, part A, shows the training dataset of the grasshopper wing. FIG. 9, part B, shows the generated result of testing data of the grasshopper wing by ^{machine} learning. FIG. 9, part C, shows a comparison of the real grasshopper wing and the generated structural form. FIG. 9, part D, shows a training dataset of the Amazon water lily. FIG. 9, part E, shows a generated result of testing data of the Amazon water lily by machine learning. FIG. 9, part F, shows a comparison of the real Amazon water lily and the generated structural form. FIG. 9, part G, shows a training dataset of the damselfly wing. FIG. 9, part H, shows a generated result of testing data of the damselfly wing by machine learning. FIG. 9, part I, shows a comparison of the real damselfly wing and the generated structural form;

FIG. 10, part (a), shows the form diagrams (Γ) of a spider web and FIG. 10, part (b), shows the force diagrams (Γ^{†}) of a spider web;

FIG. 11 shows dragonfly wing samples and their patters;

FIG. 12 illustrates data preparation, part (a) illustrates an original dragonfly wing image, part (b) shows a vectorized form of the dragonfly wing, part (c) show the result of modifying non-convex cells of the dragonfly wing (3 of 573 cells) (0.52%), part (d) illustrates a modified non-convex form of the dragonfly wing, and part (e) illustrates an internal form of the dragonfly wing;

FIG. 13 illustrates an algebraic solution of building equations to model the dragonfly wing;

FIG. 14 illustrates a geometric solution of an iterative method to update the positions of vertices to model the dragonfly wing;

FIG. 15 illustrates the maximum and average force-to-form deviations in degrees in the generation of force from the form of the dragonfly wing. Virtual loads are highlighted in green;

FIG. 16 illustrates the maximum and average force-to-form deviations in degrees in the generation of form from the force of the dragonfly wing. Virtual loads are highlighted in green;

FIG. 17 illustrates graphs of the distribution of two deviations, δ, the form-to-force deviation in degrees and δ^{†}, the force-to-form deviation in degrees;

FIG. 18 illustrates the internal structure of a dragonfly wing. Part (a) illustrates the real structure, and part (b) illustrates the generated structure. Virtual load are not shown;

FIG. 19 illustrates a comparison of original and generated structures of a dragonfly wing (internal only). Virtual loads are not shown;

FIG. 20 illustrates boundary thickness measurement based on center perpendicular pixel coordinates, and the mapping to the external force diagram. T is the thickness in pixels and L, the length in units;

FIG. 21 illustrates forms with structural thickness of the dragonfly wing. Part (a) illustrates an image of a real dragonfly wing and part (b) illustrates a generated dragonfly wing. Virtual loads are not shown;

FIG. 22 is a plot of the distribution (number of members n) of the normalized radius Rᵢ for the real dragonfly wing (orange) and the generated dragonfly wing (blue);

FIG. 23 is a flow chart of applying graph statics in generating the form and force of the dragonfly wing;

FIG. 24 illustrates a comparison of original and generated structural thickness of the dragonfly wing. Virtual loads are not shown;

FIG. 25 illustrates the extracting of the main path of the entire force. Part (a) illustrates the original force diagram, and part (b) illustrates the force diagram with main paths;

FIG. 26 illustrates main path combining the vertexes information: part (a) illustrates the original entire force diagram, and part (b) illustrates the force diagram with main paths and pixel values;

FIG. 27 illustrates examples of the machine learning model 1, 2, 3, and 5 dataset (25 pieces*5 images*7 rotating copies, 1000*600 pixels) (21 pieces as the training set, 4 pieces as the testing set);

FIG. 28 illustrates graphs of the loss of the generator (orange) and the discriminator (blue);

FIG. 29 illustrates post processing to generate the force geometry of machine learning method 2;

FIG. 30 illustrates details of the adversarial neural network (ANN); part (a) illustrates the ANN dataset preparation, and part (b) illustrates the ANN structure;

FIG. 31 illustrates categories of different dragonfly wings;

FIG. 32 explores the actual loading scenario of the dragonfly wing. We abstract the membrane and the boundary ring as triangulated members, which can only bear the tension force. By merging the tension-only membrane and boundary ring with the compression-only internal structure, the combined structural form shows a complex compression-and-tension pattern. Further, we develop an algebraic solution to calculate the tension and compression status after removing the virtual loads. It also shows a complex compression-and-tension pattern;

FIG. 33 illustrates a plot of the area and circularity of each polygon for a real grasshopper wing (orange) and the generated grasshopper wing (blue);

FIG. 34 illustrates a plot of the area and the circularity of each polygon for the real amazon water lily (orange) and thee generated amazon water lily) blue;

FIG. 35 illustrates a plot of the area and the circularity of each polygon for the real damselfly wings (orange) and the generated damselfly wings (blue);

FIG. 36 illustrates boundaries, force diagrams, and form diagrams of the generated airplane wings. Virtual loads are shown in green;

FIG. 37 illustrates renderings of generated airplane wings;

FIG. 38 illustrates the workflow and data of the web tool for generating models of internal networks of structures using boundary geometry;

FIG. 39 illustrates control parameters and functional buttons in the user input panel and the compute panel;

FIG. 40 is a flow chart illustrating the workflow in the back end and the front end of the server after the user submits input parameters;

FIG. 41 illustrates functions buttons used in the output panel and the finite element modeling control panel;

FIG. 42 illustrates functional buttons in the file manager panel;

FIG. 43 illustrates an example of an implemented web pages with panels unfolded;

FIG. 44 illustrates another example of the implemented web page with panels unfolded;

FIG. 45 illustrates examples of generated structures with different user input boundaries;

FIG. 46 illustrates examples of generated structures with different subdivision densities (SDs). Top left: SD=1.0. Top right: SD=0.75; Bottom left: SD=0.5; Bottom right: SD=0.25;

FIG. 47 illustrates examples of the generated Minkowski Sum with different stage indicators. Top left: MSI=0.05; Top right: MSI=0.35; Bottom left: MSI=0.65; Bottom right MSI=0.95;

FIG. 48 illustrates results of FEM analysis with different loading scenarios, loading materials, and structural thickness. Bottom left: point load with steel material; Bottom right: point load with steel material and larger structural thickness;

FIG. 49 illustrates structures with different minimum and maximum radius. Bottom: Exported STL model and its 3D printing view;

FIG. 50 illustrates an example of cantilever structures that could be generated using the methodology described herein;

FIG. 51 illustrates an example of the design process of the airplane wings for testing;

FIG. 52 illustrates an example of airplane wings for physical experiments; and

FIG. 53 illustrates and example of a computing platform on which a trained structural form generator as described herein may be implemented.

### DETAILED DESCRIPTION

Nature has always been the source of inspiration for designers, engineers, and scientists. Among a variety of natural structures, a dragonfly wing is an instance of a high-performance, lightweight structure that has intrigued many researchers to investigate its geometry and its performance to be used in bio-inspired design.

The subject matter described herein includes a methodology to generate the entire internal network of a wing using the boundary geometry of the wing only. In this method, we use geometry-based equilibrium methods of graphical statics (GS) to analyze the static equilibrium of the graph of the wing. In this method, the geometry of the structure is represented by a diagram called form, and the magnitude and equilibrium of forces is represented by a diagram called force. These diagrams are reciprocal, i.e., geometrically dependent and topologically dual. Graphic statics have been used to find efficient structural forms of bridges, buildings and long span structures for the past 150 years.

The geometry of the internal network of the dragonfly wing mainly includes convex cells, which may represent a compression/tension-only network on a 2D plane. The dragonfly wing can be analyzed using GS to find its force diagram and relate the thickness of the members to the magnitude of the forces in each node of the graph in equilibrium. We further used machine learning methods to generate the structural network of the dragonfly wing by using the force diagram as the training dataset for the generation process. The image-based neural networks generate the output force diagram from the input boundary image, while the vector-based neural network predicts the geometric information and completes the final structural form with the graphic statics method.

### Constructing a Force Diagram For a Given Wing Geometry

The geometry of a structural system with axial-only internal loads can be related to its force equilibrium using two geometric diagrams as proposed by Maxwell: (a) the form diagram (Γ) that represents the form of the structure, the length of members, and the locations of supports and applied loads; and (b) the force diagram (Γ^{†}) that includes of closed polygonal faces and shows the equilibrium of forces in each node of the structure. The numbers of the edges of the two diagrams are equal, and the magnitude of the force in each member of the structure is proportional to the lengths of the corresponding edge in the force diagram. This method is known as graphic statics and has been used previously to describe the force equilibrium of convex-only, natural networks such as a spider web. In the case of a dragonfly wing, the internal 2D pattern bounded by the boundary edges mainly includes convex polygons.

Thus, the method of graphic statics can be used to analyze the static equilibrium of forces in the system.

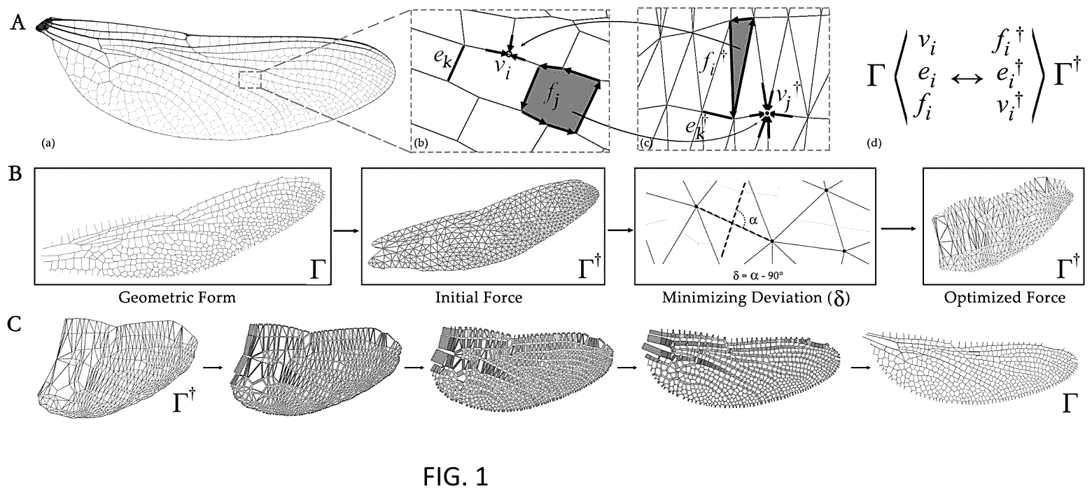

FIG. 1, part A shows the force and form of the internal structure of the dragonfly wings: (a) The form of the entire wing; (b) Internal form diagram containing vertexes (v), edges (e), and faces (ƒ); (c) Internal force diagram containing vertexes (v^{†}), edges (e^{†}), and faces (ƒ^{†}); and (d) the correspondence of the dual diagram. FIG. 1, part B is a flow chart of geometric method. FIG. 1, part C illustrates the Minkowski sum of the dragonfly wing geometry.

The geometry of the force equilibrium for the network of the wing is found using iterative methods. The wing's network will be referred to as the form diagram from which the topology of its dual/force diagram is extracted. Each polygon (ƒᵢ) in the form diagram is reciprocal to a vertex (vᵢ^{†}) in the force and vice versa. Subsequently, the edges of the force diagram are rotated iteratively to become normal to the edges of the form diagram. The difference measured from the right angle (90°) and the angle of the two corresponding edges (α) is defined as the deviation (δ). The iteration process minimizes the value of δ to derive a solution of the force diagram within the predefined tolerance (as shown in FIG. 1, part B). For example, the PolyFrame plugin can be used for this iterative operation, which is a free plugin for Rhinoceros software.

### Reconstructing a New Wing Network From the Force Diagram

The reciprocal diagrams of graphic statics allow the construction of one diagram from the other. A new geometry of the wing's network is then generated based on the calculated force diagram. The process of constructing one diagram from the other follows the same algorithm and iterative process explained in the previous section, and each method has its maximum and average deviations. The maximum deviations for the generation of the force and the form are, in some examples, 46.64° and 20.78° respectively, which happens in 0.06% of members only. In contrast, the average deviations for the two processes are, in some examples, 2.64° and 0.64°, which is relatively low. Further, the form and force diagrams can be combined using a Minkowski sum. Once the form diagram is calculated, both form and force diagrams can be integrated into a single geometry. This approach allows the transformation of one graph to the other using simple scale factors only as shown in FIG. 1, part C.

In the new form diagram, the cross-section of the members connected to each node can be sized proportionally to the edge length of the force diagram, thus resulting in a constant-stress structure. The question is whether the cross-section of the members of the actual wing matches the static force equilibrium of each node in the network. First, the force diagram is scaled to match the maximum thickness (projected cross-section on 2D) of the members in the real wing to check this property. The edges of the new form are then sized based on the force diagram to compare the member thicknesses in the real and the generated form. Our results show 91.9% accuracy, which concludes that sizing the members in the real wing may follow the static equilibrium of forces in each node.

### Making Assumptions About the Boundary Edges

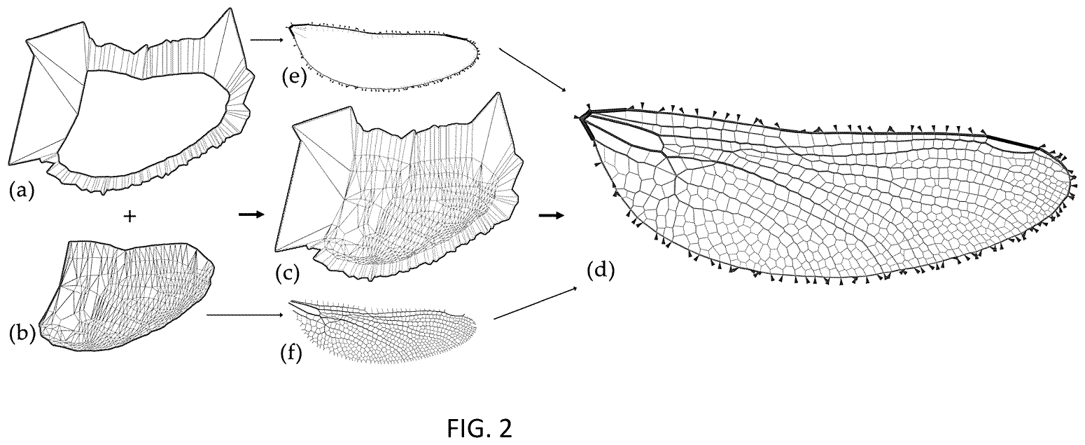

The method can be used to reconstruct the entire wing's geometry, including the external edges, if: (a) either the forces at the boundaries of the wing are given, or (b) the system is a self-stressed network. However, the external forces are unknown, and the network is not self-stressed by its edges simply because the outer polygon of the wing is not convex. For generative purposes only, a system of external forces is assumed such that if applied, (a) the entire structure of the wing will perform as a compression/tension-only structure, (b) the thickness of all members will match the thickness of the members of the actual wing. Therefore, additional edges are added in the force diagram of the internal network and are normal to the external edges of the wing, as virtual loads. Moreover, the length of the new edges of the force matches the structural thickness of the external members of the actual wing. A complete force diagram is obtained by merging the internal and external force polygons, as shown in FIG. 2. The newly reconstructed form diagram from the complete force diagram includes both internal and external edges of the wing with thicknesses proportional to the real wing.

FIG. 2 shows force and form diagrams for the entire wing: (a) external force diagram; (b) internal force diagram; (c) entire force diagram; (d) entire form diagram with virtual loads; (e) external form diagram with virtual loads; and (f) internal form diagram with virtual loads.

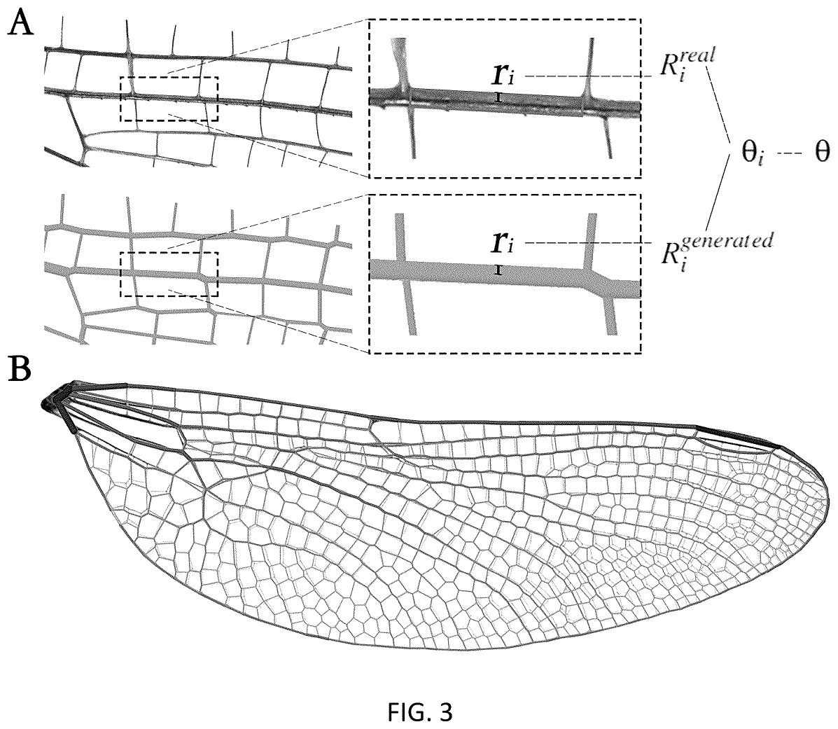

FIG. 3, part A, is a flow chart of predicting and analyzing the thickness of the dragonfly wings members. r: measured radius; R: normalized radius; θ: accuracy; θ=1−|R^{real}−R^{generated}|. FIG. 3, part B shows a comparison of the forms with structural thickness.

FIG. 3, part B, shows one example of the comparison of the generated dragonfly wing structure and the real dragonfly wing, by measuring the radius of each member (shown in FIG. 3, part A). In this example, the structural thickness is predicted with an accuracy of 92.5%. We proceeded with another 24 pieces of dragonfly wings. The results of all cases show an accuracy higher than 88.1%, while the overall average accuracy was 92.0%.

Graphic statics can be used to reconstruct a compression/tension-only network of a dragonfly wing with structural thickness proportional to the in-plane, static equilibrium of forces in each node. Moreover, the experiments indicate that the force diagram is an additional attribute of the dragonfly wing that includes structural and equilibrium information. These results lay the foundation for the generative method with no information about the initial topology of the network.

### Generating Forms Using Machine Learning Models

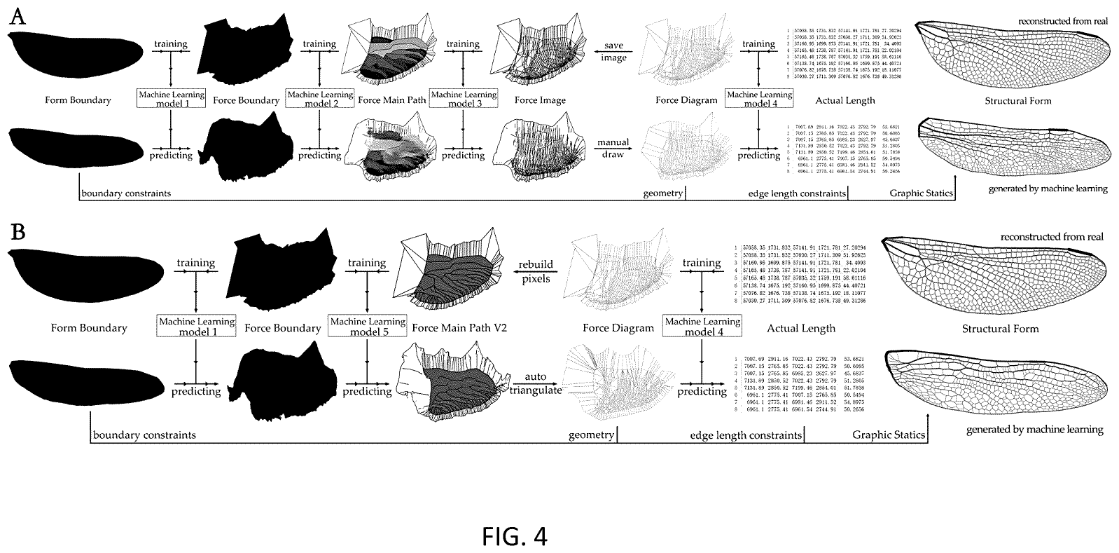

This document describes two example methods using machine learning models capable of generating the entire structural form of the wing from a user-input boundary with an intermediate product of the force diagram. FIG. 4, parts A and B, show the workflow of GAN+ANN models. FIG. 4, part A, shows method 1 with a manual process to draw the force geometry. FIG. 4, part B, shows method 2 with an automatic process to reconstruct the force geometry.

In the first method (FIG. 4, part A), to build the training and testing dataset for the machine learning models, geometries in different stages are transformed into images. A similar method can be used to extract the main path of the force diagram of the dragonfly wing. Then, image-to-image machine learning models are used to learn the mapping between each stage of the dragonfly wing data and generate the force diagram from the form boundary as an image. Finally, a dataset of 25 pieces of dragonfly wings is collected, in which the first 21 pieces are used as the training set and the remaining four pieces are used as the testing set.

In addition, a vector-based machine learning model is trained to predict the edge lengths of the form diagram using a dataset of the edge lengths extracted from the dragonfly wing geometries. Therefore, the four machine learning models can predict all information needed to generate the structural form of the wing. To be specific, with the generated force diagram, the image data is first transformed from line drawings into vectorized data as line geometries. However, the force diagram represents the topological information of the structural form; the geometric information, including the edge lengths for the form diagram, is still missing. Therefore, another vector-based machine learning model of Artificial Neural Network (ANN) is proposed to learn and predict the edge lengths of the form diagram. Following a similar process, the trained ANN provides the edge lengths of the corresponding form for each edge in the force, and the complete structural form is generated.

However, in the first method, the geometries of a force diagram need to be reconstructed from the image manually to maintain the precision. To automatically generate the force geometry, we develop the second method that represents the vertex information as the pixel values in the main path image and triangulates the regions in the main path according to the recognized vertexes (FIG. 4, part B). Thus, the force geometry can be directly generated and proceeded into the structural form. The first method produces more visible information for a human to understand, while the second method generates abstract information for the machine to rebuild the geometry.

To test the performance of the overall workflow, a testing dataset with three categories of the dragonfly wings can be used, including top and bottom wings for male dragonflies and bottom wings for female dragonflies. In the samples of the three categories, the top wings of male and female are the same, while the bottom wings are different. Thus the testing dataset contains the input (form boundary) and the output (structural form) of dragonfly wings in these three categories.

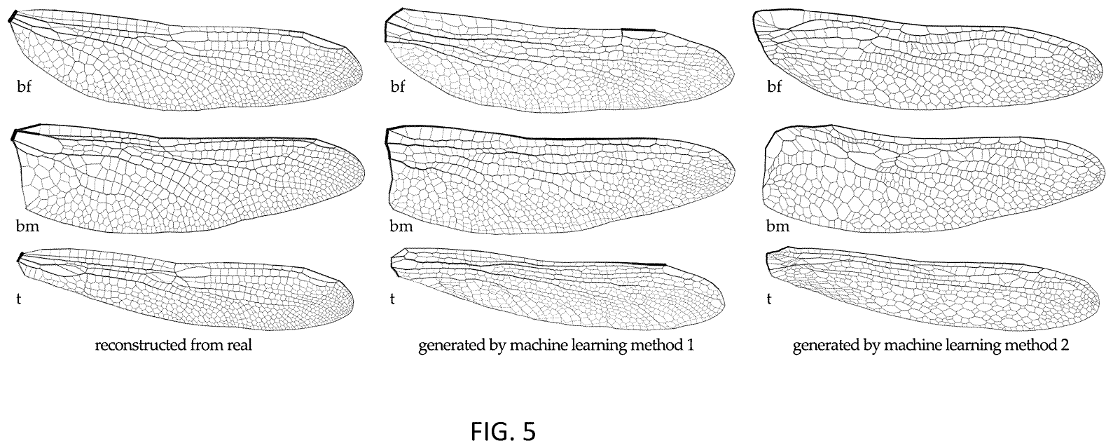

FIG. 5 shows the comparison of the real and the generated dragonfly wings in the three categories. Regarding the naming: b/t: bottom/top; m/f: male/female.

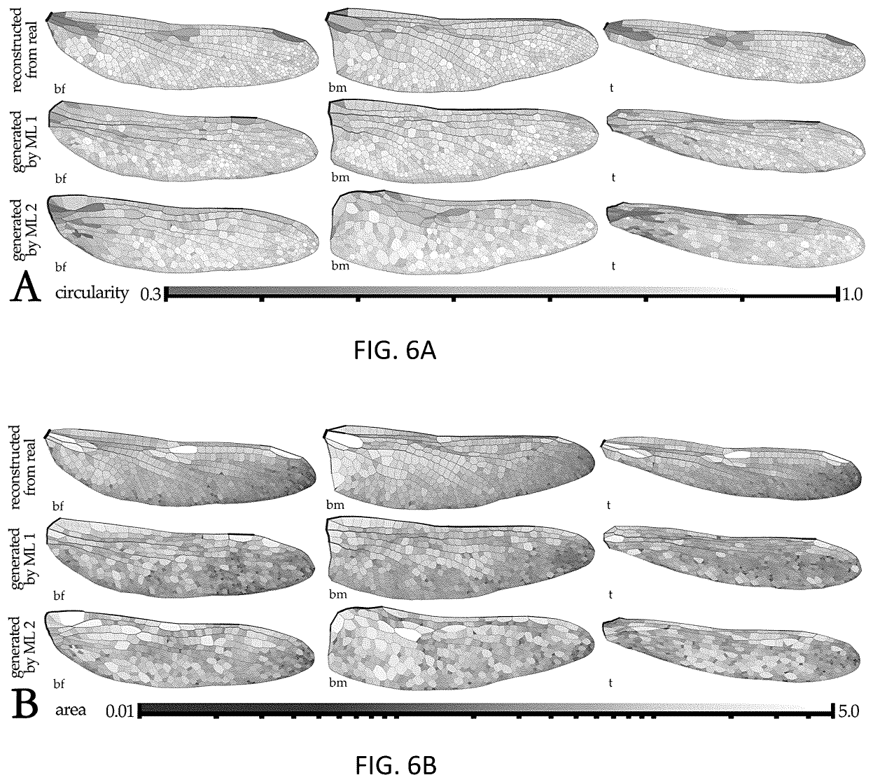

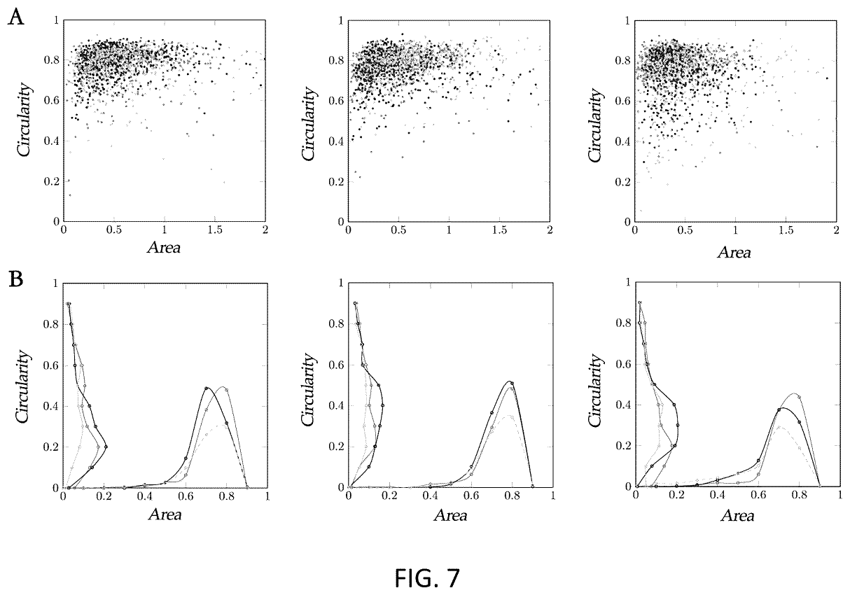

To compare the similarity of the wing pairs, the evaluation method based on the area and the circularity of each cell in the wing pattern is implemented. FIGS. 6A and 6B show the visualization of the two measures, while FIG. 7 shows the plot diagrams. FIG. 6A shows the visualization of the circularity measure on the wing polygons. FIG. 6B shows the visualization of the area measure on the wing polygons.

FIG. 7, part A, illustrates plots of the area and the circularity of each polygon for the real wing and the generated wings. Top: sample bf; Middle: sample bm; and Bottom: sample t. FIG. 7, part B, shows the smooth curve of the area and the circularity of each polygon for the real wing and the generated wing. Top: sample bf; Middle: sample bm; and Bottom: sample t.

In the scatter plot (FIG. 7, part A), the scatters for the real and the generated dragonfly wings are generally close and overlapped. For the cells with similar areas, the circularity of the generated dragonfly wings is higher, while for the cells with similar circularity, the area of the generated dragonfly wings is higher. This phenomenon might be caused by the deviation in the graphic statics when generating the form diagram from the force diagram. The deviation makes the angles in the cells of the form diagram shifted compared with the designed angles in the force diagram. Meanwhile, the distribution map (FIG. 7, part B) also proves the above observation. But generally speaking, the generated dragonfly wings are similar to the real dragonfly wings. The method successfully generates the structural form of the dragonfly wing from its form boundary.

### Application of Designing an Airplane Wing

In the broader application of engineering and design fields, the design of a nature-inspired structure can be achieved using the methods and systems described in this document. With the trained models, we can input the boundary (e.g., a human-defined boundary) and control the machine learning model to generate the structural form within the boundary.

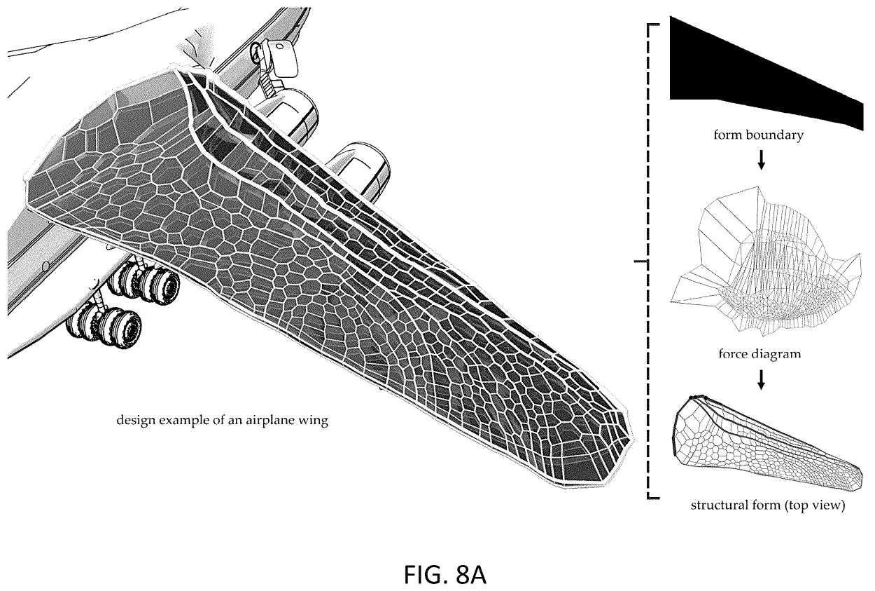

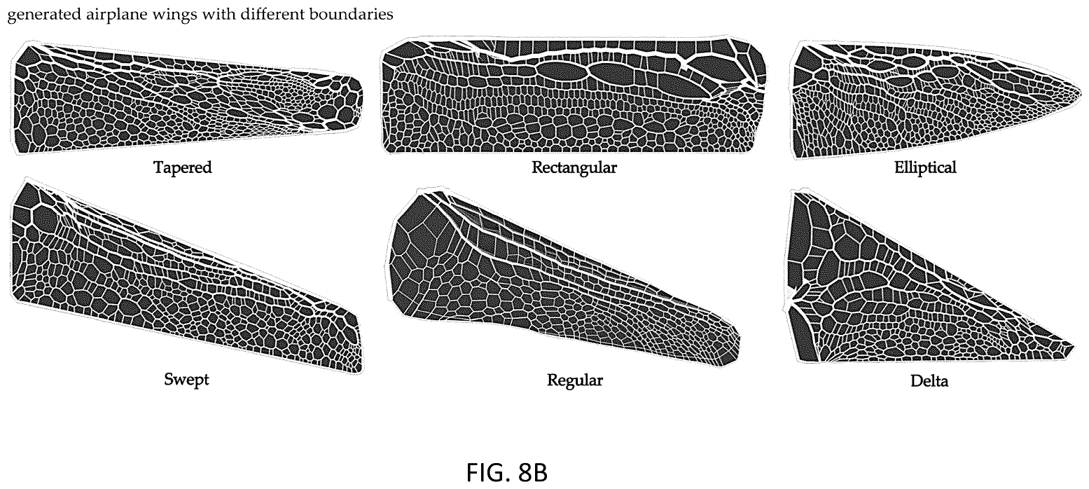

FIGS. 8A and 8B show one of the applications of designing an airplane wing. We learn from the dragonfly that the design needs larger external force in the front compared to smaller external forces in the back. The generated force diagram matches this principle, and the structural form contains similar features as the dragonfly wing. In addition, by modifying the 2D force diagram into 3D geometries with forces represented as inclined closed polyhedrons, the overall curvature can be created, which matches the section of a real airplane wing.

To test whether our generated structures perform better than traditional designs of airplane wings, we inputted the boundary of an airplane wing, generated eight results with different structural thickness and subdivision density, and compared the structural performance with the original results. Similar structures such as cantilever roofs and floors can also be generated using the same algorithm.

### Testing Other Species With Convex Networks

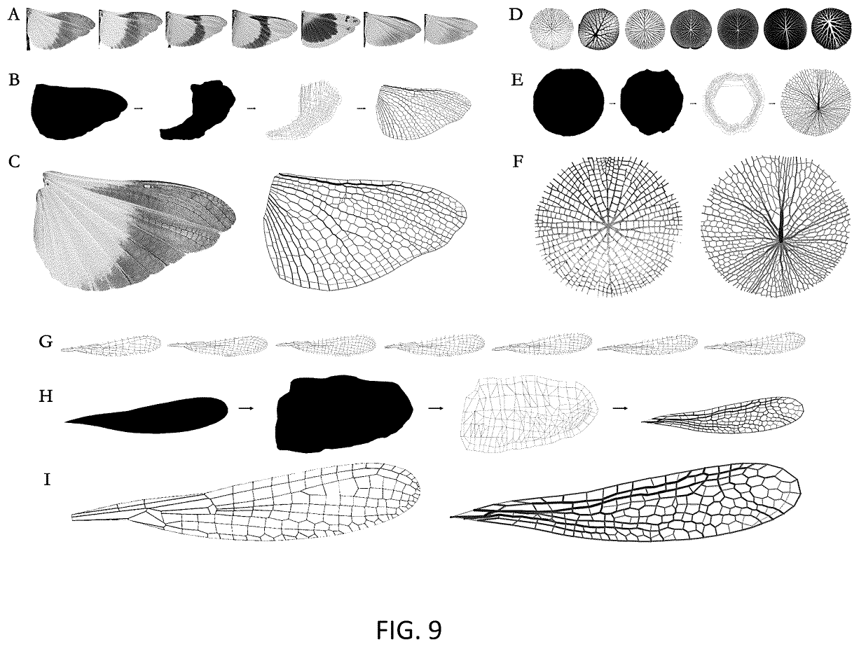

Besides the training dataset for the dragonfly wings, the training and testing data for other species can be collected and used with the methods and systems described in this document. The following section describes tests on the graphic statics and machine learning method works in generating patterns in other species as a general applicable method. FIG. 9 shows the details of the datasets and the results of the species (grasshopper wing, Amazon water lily, and damselfly wing). For each test, seven pieces of image are collected, 6 of which become the training dataset while the rest one is used as the testing case.

FIG. 9, part A, shows the training dataset of the grasshopper wing. FIG. 9, part B, shows the generated result of testing data of the grasshopper wing by machine learning. FIG. 9, part C, shows a comparison of the real grasshopper wing and the generated structural form. FIG. 9, part D, shows a training dataset of the Amazon water lily. FIG. 9, part E, shows a generated result of testing data of the Amazon water lily by machine learning. FIG. 9, part F, shows a comparison of the real Amazon water lily and the generated structural form. FIG. 9, part G, shows a training dataset of the damselfly wing. FIG. 9, part H, shows a generated result of testing data of the damselfly wing by machine learning. FIG. 9, part I, shows a comparison of the real damselfly wing and the generated structural form.

The grasshopper wing is selected as the first experimental object since it is similar to the dragonfly wing. To be specific, the dataset contains 7 pieces of the grasshopper wings (FIG. 9, part A), 6 of them become the training dataset and the rest 1 becomes the testing dataset. The GAN+ANN workflow (FIG. 9, part B) is similar to the original workflow for the dragonfly wing. FIG. 9, part C, shows the result comparison of the real grasshopper wing and the generated structural form. The generated pattern has fewer members than the real pattern, especially in the domain with small area and small circularity. But the overall distribution, especially for the main veins, is accurate. The method performs as expected with a smaller training dataset in grasshopper wings.

Besides insect wings, some plants also have unique patterns in their rhizomes, for example, the Amazon water lily. The rhizomes of the amazon water lily serve as a supporting structure to hold its leaves, while the leaves provide buoyancy to make the amazon water lily float on the water. Therefore, the structure of the Amazon water lily might have similar structural properties as the dragonfly and the grasshopper wings, and it is worth exploring. To be specific, we have also collected a small dataset of 7 pieces of amazon water lilies (FIG. 9, part D). FIG. 9, part E, shows a similar workflow of the case of the Amazon water lily as the case of the grasshopper wing. FIG. 9, part F, shows the comparison of the result and the analytical plots. However, in the case of the Amazon water lily, the generated pattern has more members than the real pattern, especially in the domain with small area and small circularity. There are more veins generated. The overall distribution is still acceptable.

Similarly, the method was tested damselfly wings (FIG. 9, part G). The workflow (FIG. 9, part H) and the result comparison (FIG. 9, part I) further proves the generality of our method. From above observation, the conclusion can be reached that the graphic statics and machine learning method can be widely applied to generate structures by learning from natural species.

### Discussion

Using machine learning techniques to learn the force diagram, the intrinsic rules can be rebuilt as surrogate models, which can then be applied in generative tasks using the models. The system can use machine learning techniques to learn the mapping between each stage of dragonfly wing data and produce the force diagram from the form boundary. Together with the graphic statics method, machine learning can learn the force diagrams from a dragonfly wing as a compression-only network, thus helping reveal and reproduce the design rules of the dragonfly wing from the perspective of structural engineering.

Combining graphic statics and machine learning can produce one or more of the following advantages. First, the training of the machine learning surrogate model starts with a clear definition of the dataset, which matches the exported force pattern of the compression-only form. The force pattern of the compression-only form shows the analytical result of the structural form as the force diagram. It can be regarded as output data for the machine learning model; thus, together with the input boundary information, it can enable the training of the machine learning models.

Second, compared with other analytical results, for example, the FEM analysis, the force diagram can be expressed as images that can be learned and generated by machine learning models. Moreover, the form diagram can be regenerated with the generated force diagram; thus, the information in the force diagram can represent both the topological and the geometric data, making the machine learning model into a generative model rather than an analytical model. Last, regarding the dragonfly wing as a compression-only form is actually a simplification of a variety of layered information. With a limited size dataset, the machine learning model can be trained with clearer data without noise from unrelated or little-related information. This simplification reduces the amount of noise features and ensures that the training process can be efficient and successful.

The subject matter described herein includes the use of a geometry-based equilibrium method known as graphic statics combined with machine learning techniques to analyze, reconstruct and generate structural geometry of the network of a dragonfly wing. The network's convex geometry can be considered a compression/tension-only network, and thus, an additional reciprocal diagram can be extracted from the network. The reciprocal diagram shows the in-plane equilibrium of forces in the nodes of the internal network of the real wing.

The graphic statics method can be used to transform the geometries between the form diagram and the force diagram of the dragonfly wing. By generating the force diagram and measuring the force magnitude, the structural thickness can be predicted. The structural form generated by our method is very similar to the real structural form, which proves that the graphic statics method can be used to analyze the structural form of the dragonfly wing. As a secondary conclusion, the experiments indicate that the force diagram is another representative of the dragonfly wing besides the form diagram. It reveals the intrinsic logic of the generation of the geometries and the thickness of the dragonfly wing. Therefore, the force diagram contains structural information that is also helpful for further research on the dragonfly wing structures.

In the machine learning method, we inherit from the discovery of the graphic statics method, use the force diagram as the learning materials for training the machine learning models. The image-based neural networks proceed the input boundary image into the output force diagram, while the vector-based neural networks predict the geometric information and help generate the final structural form with the graphic statics method. The quantitative analysis and the comparison of the real and the generated results show the metrics of evaluation.

The method generates the entire pattern from the boundary without any other input information. Designers can input a customized boundary and generate the entire pattern directly. In addition, the method not only generates the geometry, but also predicts the structural thickness, which enables the form to stand by itself from the perspective of structural engineering.

In some examples, a larger dataset is used for the system to increase the accuracy of the generated results. In some examples, 3D/polyhedral graphic statics are used in generating three-dimensional structures of the wing. The structure of the wing includes veins and additional surfaces that restrains the kinematic degrees of freedom of the network; these faces can be included in the models of the system in some examples.

### Experimental Section

The Supplemental Materials section below includes further details and examples regarding the methods and systems described herein. The following section briefly describes the methods and system developed for the experiments described above.

Graphic statics is a geometry-based method, where the equilibrium of force is shown by geometric diagrams. In 2D graphic statics, the force diagram shows the force magnitude of the corresponding form diagram. The length of each edge in the force diagram represents the force magnitude of the corresponding edge in the form diagram. The geometric transformation between the force diagram and the form diagram can be achieved using graphic statics method.

The first step is to exclude the boundary edges of the dragonfly wing and consider the internal network of the edges. The original dragonfly wing image is transformed into the vector-based geometry with convex and non-convex polygons using image processing techniques. The non-convex polygons are slightly adjusted to make convex polygons. This allows the graphic statics method to work on the compression-only networks. By removing the boundary edges, the internal form is generated.

For example, an iterative method of PolyFrame () can be used to generate the geometries of the force diagram with a deviation (tolerance). The algorithm starts from constructing the graph of the force diagram with incorrect edge lengths. Each polygon (ƒᵢ) in the form is transformed into a vertex (vᵢ^{†}) in the force. Then the iterative method is applied to optimize the position of each vertex (vᵢ^{†}′) to make the corresponding edges perpendicular. The difference between the vertical angle (90°) and the angle of the two corresponding edges (α) is defined as the deviation (δ). The optimization process works by a loop to minimize the value of δ. With this geometric method, an approximate solution of the force diagram can be generated.

To prove the consistency of the form and force in the dragonfly wing, experiments were executed taking the dataset of the dragonfly wings as examples. First, using graphic statics method, the force diagram can be generated from the form diagram of the dragonfly wing (form-to-force). Then, the form diagram can be re-generated from the generated force diagram using the same method (force-to-form).

With the force diagram, the internal force for each form member can be obtained, thus the structural thickness can be inferred, which is proportional to the force magnitude. With the above experiments on the internal force and form, we further investigate the external force and form of the dragonfly wing. The purpose of adding the external force is to represent the structural thickness of the boundary members, thus we regard the external force pattern as a set of compression forces acting from the boundary. Although the actual external force pattern might be different and complicated, this modification can construct the entire force diagram as a compression-only force pattern, thus the structural thickness of the entire wing can be predicted.

Lastly, we conclude by partially removing the structural thickness from the original dragonfly wing image, with only the geometry of the wing left. Then, our graphic statics method transforms the geometry of the form into the geometry of the force. By mapping the edge lengths in the force geometry to the structural thickness of the edge in the form geometry, the wing is generated again with the predicted structural thickness. The accuracy of the comparison of the real and the generated dragonfly wings is high, which shows the evidence that: 1) graphic statics method can be used to analyze the dragonfly wing structures; 2) the intrinsic logic of the structural property of the dragonfly wing can be represented as the force diagram.

FIG. 3, parts A and B, shows the two methods we develop. For the first method, the entire process starts from training three machine learning models, in which the first model learns the mapping between the form boundary and the force boundary, the second model learns the mapping between the force boundary and the force main path, and the third model learns the mapping between the force main path and the force diagram. However, in the first method, the geometries of a force diagram need to be reconstructed from the image manually to maintain the precision. To automatically generate the force geometry, we develop the second method that trains the main path image with vertexes information, and triangulates the regions in the main path according to the recognized vertexes. Thus, the force geometry can be directly generated and proceeded into the structural form. The first method produces more visible information for human to understand, while the second method generates abstract information for the machine to rebuild the geometry. Since the force diagram is representative of the structural form and it contains enough geometric information, the process in this step ends with the generation of the force diagram, and the following process regarding the generation of the structural form from the force diagram is introduced in the following sections.

The force diagram can only represent the topological information of the structural form, the geometric information (edge lengths for the form diagram) is still missing. Therefore, in order to learn and predict the edge lengths, another vector-based machine learning model of Artificial Neural Network (ANN) can be sued. In the workflow of ANN, the dual diagram of the force geometry is first generated by the graphic statics method. Then for each edge in the dual diagram, a vector (x1, y1, x2, y2, ƒ) is generated, which represents the coordinates of the start and end points and the force magnitude (length for the corresponding edge in the force diagram). In addition, the corresponding edge length in the real form is found, together with the vector, becomes the input and output of the ANN. Once trained, the ANN can predict the actual edge length for each edge in the dual diagram, thus helping generate the structural form using the graphic statics method.

Although specific examples and features have been described above, these examples and features are not intended to limit the scope of the present disclosure, even where only a single example is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

### Supplemental Materials

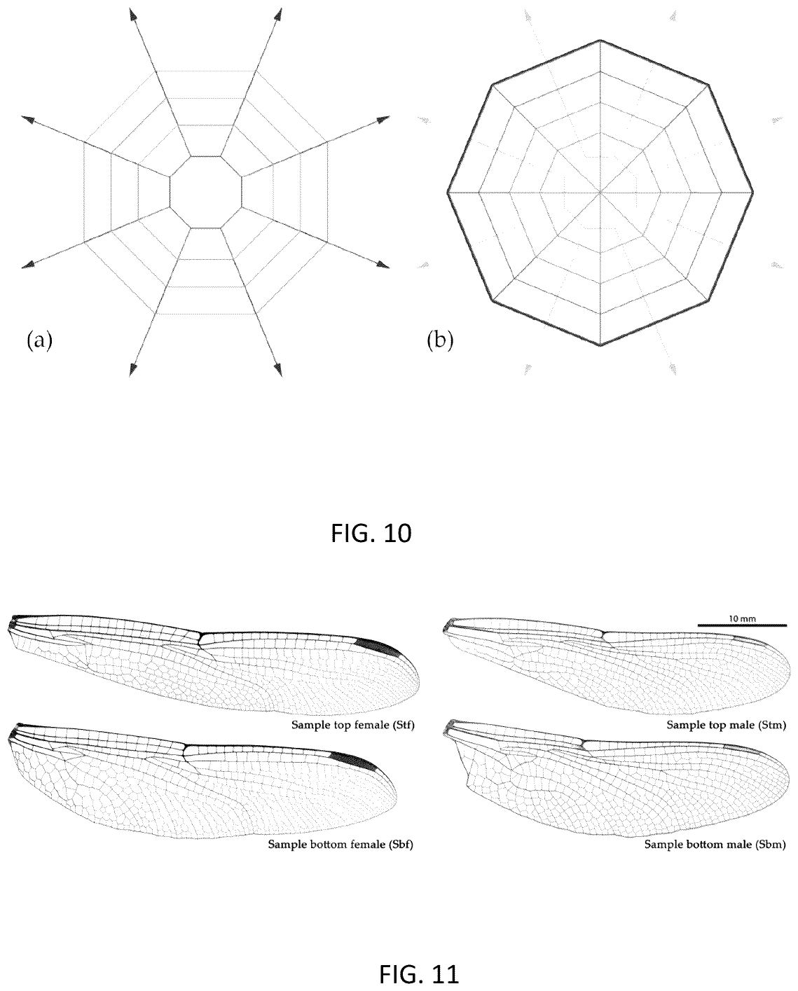

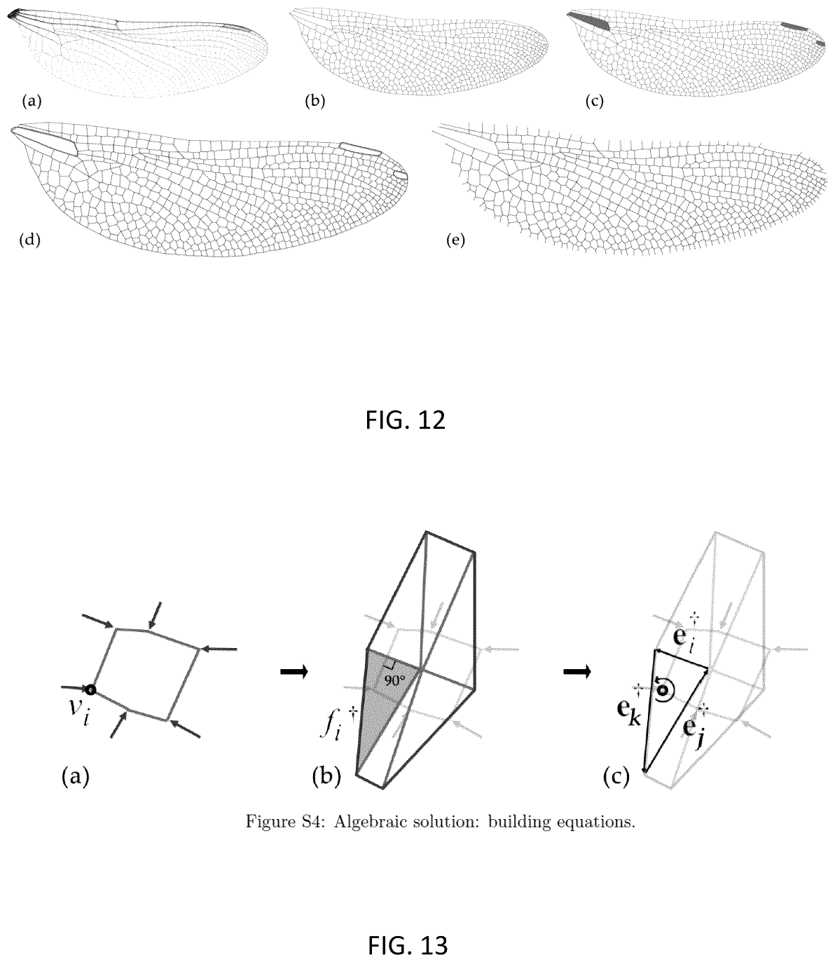

FIG. 10, part (a) illustrates the form diagrams (Γ), and part (b) illustrates the force diagrams (Γ^{†}) of a spider web. FIG. 11 illustrates dragonfly wing samples and their patterns. FIG. 12 illustrates data preparation. Part (a) illustrates the original dragonfly wing image. Part (b) illustrates the vectorized form. Part (c) illustrates modifying non-convex cells (3 out of 573 (0.52%) cells). Part (d) illustrates the modified convex form. Part (e) illustrates the internal form.

In the case of the dragonfly wing (FIG. 11) [1], its 2D pattern can be regarded as a structural form, which contains a group of closed polygons and each edge of the polygons has a unique structural thickness. The geometry of the internal members of the dragonfly wing mainly consists of convex cell, which may in turn represent a compression-only network on a 2D plane. Therefore, the internal loading scenarios can be simplified into a compression-only form of the veins, making it possible to quantitatively analyze and manipulate this information. This phenomenon suggests a possibility to analyze the dragonfly wing from the perspective of structural engineering.

The simplified version of the dragonfly wing contains only the geometric information, it is a representative form diagram of the dragonfly wing. Using graphic statics method, its corresponding force diagram can be generated (FIG. 1, part A). The graphic statics method provides a possibility for the dragonfly wing to be regarded as a compression-only network. To better use graphic statics to extract the force diagram, we assume the entire dragonfly wing as a self-stressed system, in which the internal members bear axial compression forces, while the boundary members and the membrane together bear other forces. Therefore, the internal structure represents a compression-only form, and the rest represents a tension-compression-mixed structure, thus the force diagram can be extracted from the form. This workflow simplifies the complicated loading environment, making it possible to analyze and generate the dragonfly wing from a generalized perspective. Finally, by mapping the force magnitude to the structural thickness, the corresponding structural form can be re-generated. The first goal of this research is to compare our generated dragonfly wings with the real dragonfly wings, and show whether the force distribution in the real dragonfly wing follows the rules of graphic statics. Once proven, the force diagram can explain the intrinsic logic of the design of the dragonfly wing by nature.

To generate the force diagram based on the internal form diagram. In 2D graphic statics, each edge in the force diagram is perpendicular to the corresponding edge in the form diagram. FIG. 13, part (a), shows a form diagram, which contains six internal edges and six external forces (edges). In FIG. 13, part (b), the proposed edges are presented as the dark blue lines, which are perpendicular to the edges in FIG. 13, part (a). Therefore, each vertex (vᵢ) in the form diagram has a dual polygon (ƒᵢ^{†}) in the force diagram. For each polygon (ƒᵢ^{†}), a group of equations can be derived based on its edges (eᵢ^{†}) (FIG. 13, part (c)).

Indeed, since the face ƒᵢ^{†} is a closed polygon, the sum of its edge vectors eⱼ^{†}should be zero. Hence, we obtain a vector equation

$${\sum }_{{e}_{j}^{†}} {u}_{j}^{†} {q}_{j} = 0$$

where the sum runs over the edges eⱼ^{†} of the face ƒᵢ^{†}, uⱼ^{†} denotes the unit edge vector of the edge eⱼ^{†}, and the qⱼ are the variables representing the lengths of the edges eⱼ^{†}. Writing these equations around every face ƒᵢ^{†} provides a linear equation system for the edge length vector q which can be described by a [2v×e] matrix, called the equilibrium matrix A:

$$A q = 0 . \qquad ( 1 )$$

If the equilibrium matrix, A is of full rank (or the Geometric Degrees of Freedom (GDOF) is zero), then the only solution to Eq. (1) is the zero vector q=0. In this case, the force diagram collapses to a point. However, after experiments, we found that most of the dragonfly wings in our dataset have a GDOF of 0, which means there are no accurate solutions for most of the cases. Thus, the algebraic solution is not stably applicable in all the cases of the dragonfly wing.

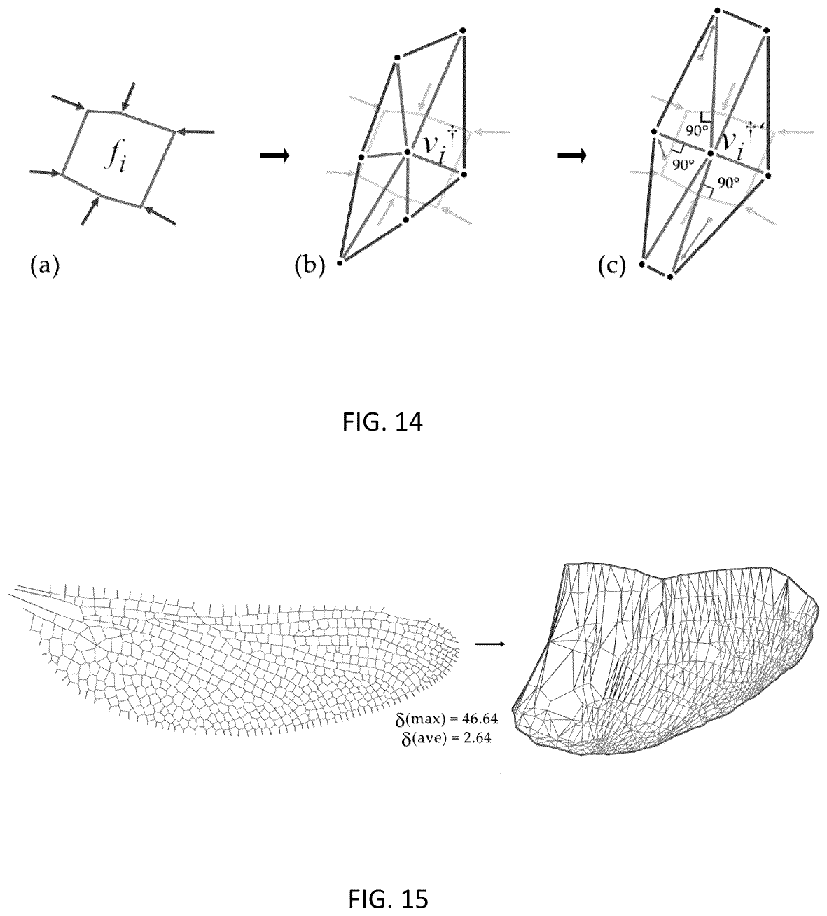

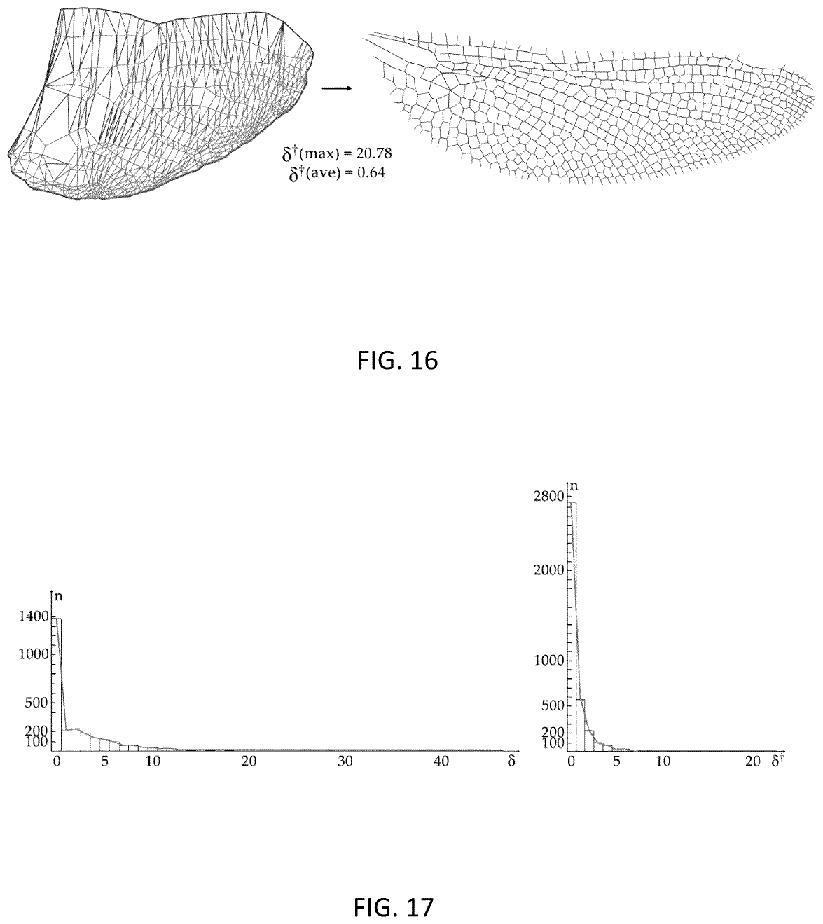

FIG. 14 illustrates a geometric solution: an iterative method to update the positions of vertices. FIG. 15 illustrates the maximum and average form-to-force deviations in degrees (δ) in the generation of force from the form. (The virtual loads are highlighted as green.) FIG. 16 illustrates the maximum and average force-to-form deviations in degrees (δ^{†}) in the generation of form from the force. (The virtual loads are highlighted as green.)

TABLE 1
Deviation and accuracy for FIG. 19: δ: form-to-force deviation degrees;
δ^{†}: force-to-form deviation in degrees; and θ: accuracy.

| | δ | δ | % | δ^{†} | δ^{†} | % | |
|---|---|---|---|---|---|---|---|
| Sample | (max) | (ave) | (<5°) | (max) | (ave) | (<5°) | θ |
| 1-tf | 52.26 | 2.37 | 0.83013 | 21.54 | 0.57 | 0.98245 | 0.922349 |
| 2-bm | 44.76 | 2.72 | 0.78754 | 17.44 | 0.69 | 0.97179 | 0.922321 |
| 2-tm | 42.04 | 2.57 | 0.82237 | 42.68 | 0.69 | 0.97446 | 0.935846 |
| 3-bf | 55.61 | 2.81 | 0.78835 | 38.69 | 0.68 | 0.98546 | 0.891284 |
| 3-tf | 35.35 | 3.13 | 0.76083 | 30.45 | 0.68 | 0.98846 | 0.923929 |
| 4-bm | 38.43 | 3.01 | 0.76544 | 29.68 | 0.70 | 0.98057 | 0.917173 |
| Average | 44.74 | 2.77 | 0.78833 | 30.08 | 0.67 | 0.97624 | 0.918817 |

FIG. 17 illustrates the distribution of two deviations. δ: form-to-force deviation in degrees. δ^{†}: force-to-form deviation in degrees. n: number of members. The maximum deviations for the form-to-force and the force-to-form processes are 46.64° and 20.78°, while the average deviations for the two processes are 2.64° and 0.64°. Therefore, the geometric method successfully transforms the force diagram and the form diagram with small values of average deviations.

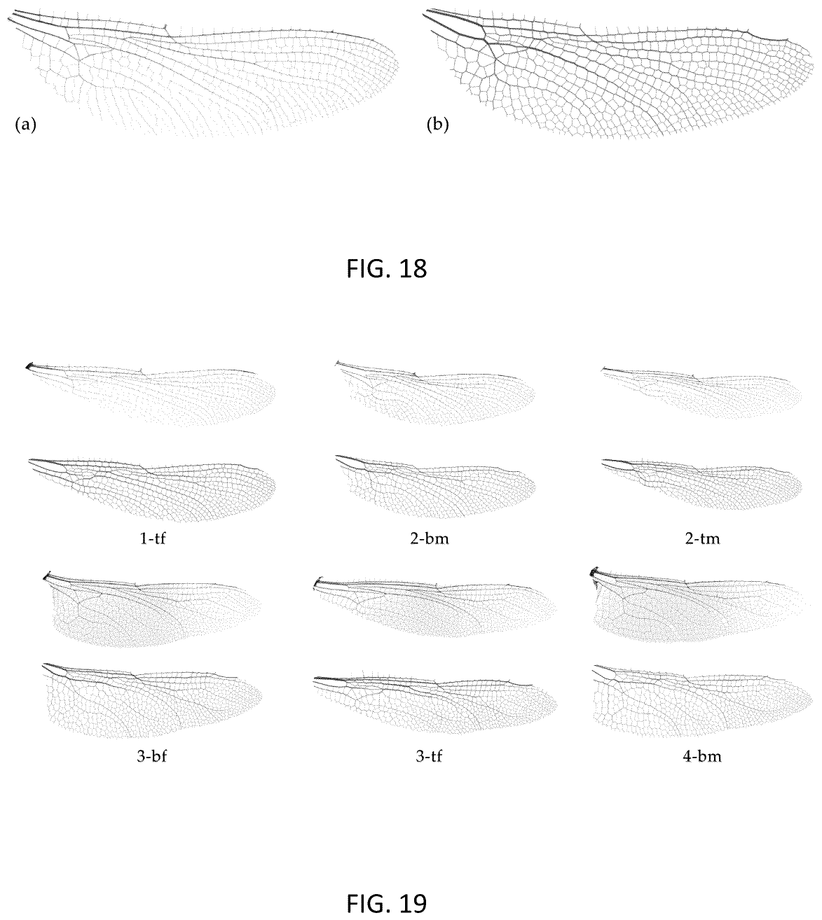

FIG. 18 shows the distribution of the deviation of the form-to-force and the force-to-form generation. Most of the members have a deviation smaller than 1°, and there are decreasing numbers of members as the deviation increases. Only a few members have a deviation larger than 20° in the form-to-force process and 10° in the force-to-form process. Therefore, most of the members in the force diagram are accurately generated according to the corresponding form diagram, with the meaning of the internal force magnitude.

FIG. 18 illustrates the Internal structure of a dragonfly wing. Part (a) illustrates the real structure. Part (b) illustrates the generated structure. The virtual loads are not shown.

FIG. 19 illustrates a comparison of the original and the generated structural thickness (internal only). The virtual loads are not shown.

In order to compare the similarity of the real and the generated internal wing, the accuracy measure (θ) is defined as the following process (FIG. 2, part A). First, the radius of each structural member is extracted as rᵢ, and the normalized radius Rᵢ is calculated (Equation 2), thus the value range of Rᵢ is 0 to 1. Second, for each member in the real and the generated dragonfly wing, the accuracy θᵢ is calculated based on the absolute error of these two values (Equation 3). Last, the overall accuracy θ is the weighted average of all θᵢ based on the volume Vᵢ of each member (Equation 4).

$${R}_{i} = \frac{{r}_{i} - min ( r )}{max ( r ) - min ( r )} \qquad ( 2 )$$

$${θ}_{i} = 1 - \vert {R}_{i}^{real} - {R}_{i}^{generated} \vert \qquad ( 3 )$$

$$θ = \frac{{\sum }_{i = 1}^{N} {θ}_{i} \cdot {V}_{i}}{{\sum }_{i = 1}^{N} {V}_{i}} \qquad ( 4 )$$

According to the statistics, in the force-to-form generation, all the six testing wings have an average deviation of 2.77°, and 78.83% of the members have a deviation smaller than 5°. In the form-to-force generation, the average deviation is 0.97° and 97.62% of the members have a deviation smaller than 5°. The overall accuracy is 91.9%, which shows a high similarity of the generated and the real internal dragonfly wing.

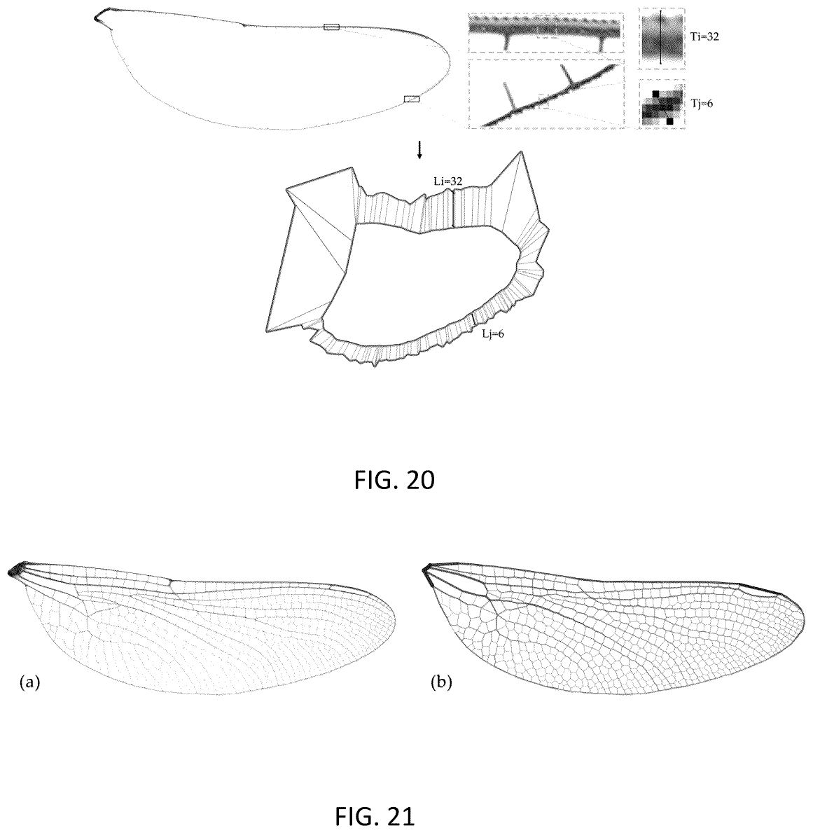

FIG. 20 illustrates boundary thickness measurement based on the center perpendicular pixel coordinates, and the mapping to the external force diagram. T: the thickness in pixels; and L: the length in units. Since the external force cannot be extracted directly from the form diagram, we measure the thickness of the external edges in the structural form of the wing, and map the pixel counts to the lengths of the corresponding edges in the force diagram (FIG. 20). Each edge in the force should be perpendicular to the boundary of the form, thus both the lengths and the directions can be inferred from the original form image. With this method, the external force diagram can be generated with correct length values.

FIG. 21 illustrates forms with structural thickness. Part (a) illustrates an image of a real dragonfly wing. Part (b) illustrates a generated image of a dragonfly wing. The virtual loads are not shown.

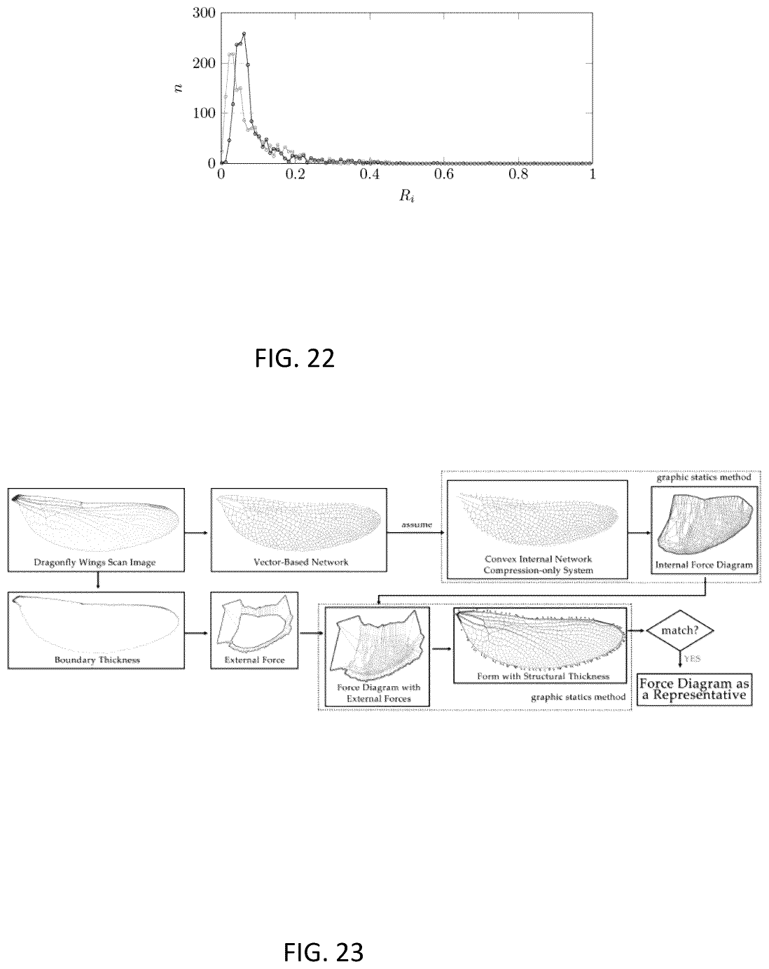

FIG. 22 is a plot of the distribution (number of members n) of the normalizes radius (Rᵢ) for the real dragonfly wing (orange) and the generated dragonfly wing (blue). FIG. 23 is a flow chart of applying graphic statics in generating the form and force of the dragonfly wing. With the external force diagram (FIG. 2 part (a)), the entire force diagram (FIG. 2, part (c)) can be obtained by merging the internal (FIG. 2, part (b)) and external force diagram. By transforming the entire force diagram back to the structural form, the structural thickness of the entire wing can be inferred, thus the predicted dragonfly wing is complete with both internal and external members (FIG. 2, part (d)).

FIG. 23 shows one example of the comparison of the real dragonfly wing and our generated dragonfly wing. Using our graphic statics method, the structural thickness is accurately predicted with an accuracy of 92.5%. FIG. 22 shows the plot of the normalized radius (Rᵢ) of the real and the generated dragonfly wings. The distributions of the thickness are highly similar, which further shows a high accuracy of the prediction.

Considering the entire wings with both the internal and external members, it shows similar results comparing with the internal-only testing. The form-to-force generations for all the 24 cases have an average deviation smaller than 3.3°, and the overall average deviation is 2.79°. In the force-to-form generation, the average deviation for each case is smaller than 1° and the overall deviation is 0.73°. And all cases show an accuracy higher than 88.1%, and the overall average accuracy is 92.0%. Therefore, through the comparison of more pieces of dragonfly wings, the high accuracy of the comparison of the real and the generated dragonfly wings shows the evidence that: 1) graphic statics method can be used to analyze the dragonfly wing structures; 2) the intrinsic logic of the structural characteristics of the dragonfly wing can be represented as the force diagram.

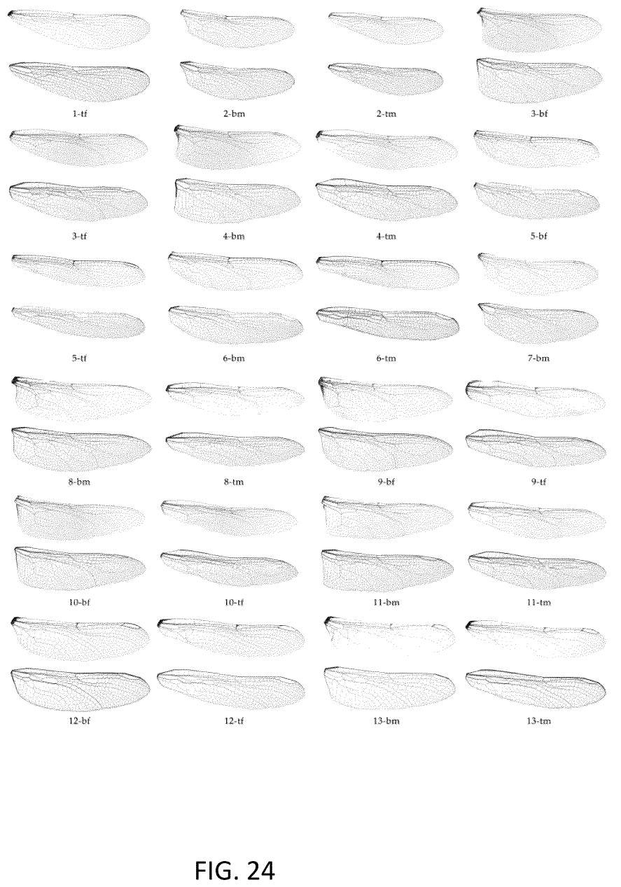

FIG. 24 illustrates a comparison of the original and the generated structural thickness. The virtual loads are not shown. Table 2 shows the values for the structures in FIG. 24.

TABLE 2
Values for Structures in FIG. 24

| | δ | δ | % | δ^{†} | δ^{†} | % | |
|---|---|---|---|---|---|---|---|
| Sample | (max) | (ave) | (<5°) | (max) | (ave) | (<5°) | θ |
| 1-tf | 52.26 | 2.37 | 0.830133 | 23.11 | 0.59 | 0.981198 | 0.928593 |
| 2-bm | 44.76 | 2.72 | 0.78754 | 16.89 | 0.68 | 0.971799 | 0.935975 |
| 2-tm | 42.04 | 2.57 | 0.822371 | 43.52 | 0.69 | 0.974462 | 0.938333 |
| 3-bf | 55.61 | 2.81 | 0.78835 | 39.83 | 0.71 | 0.976597 | 0.90185 |
| 3-tf | 35.35 | 3.13 | 0.760836 | 32.45 | 0.74 | 0.973422 | 0.932262 |
| 4-bm | 38.43 | 3.01 | 0.76544 | 31.96 | 0.75 | 0.96969 | 0.918975 |
| 4-tm | 55.01 | 3.08 | 0.769002 | 25.7 | 0.69 | 0.975466 | 0.933478 |
| 5-bf | 56.61 | 2.8 | 0.790818 | 22.98 | 0.71 | 0.971765 | 0.934398 |
| 5-tf | 58.88 | 2.8 | 0.798701 | 29.23 | 0.73 | 0.968781 | 0.929365 |
| 6-bm | 85.4 | 2.7 | 0.795924 | 38.76 | 0.69 | 0.976645 | 0.940173 |
| 6-tm | 41.53 | 3.24 | 0.781451 | 40.95 | 0.87 | 0.973387 | 0.911666 |
| 7-bm | 48.28 | 2.83 | 0.786388 | 26.26 | 0.76 | 0.96688 | 0.927764 |
| 8-bm | 27.71 | 2.45 | 0.812821 | 30.98 | 0.58 | 0.980793 | 0.907822 |
| 8-tm | 42.67 | 2.65 | 0.811239 | 23.43 | 0.62 | 0.980288 | 0.930594 |
| 9-bf | 45.76 | 2.91 | 0.775819 | 36.79 | 0.78 | 0.970803 | 0.881393 |
| 9-tf | 51.55 | 3.16 | 0.765987 | 59.71 | 0.91 | 0.963 | 0.901833 |
| 10-bf | 50.87 | 2.63 | 0.799039 | 25.26 | 0.72 | 0.974135 | 0.915933 |
| 10-tf | 40.58 | 2.9 | 0.777516 | 54.73 | 0.73 | 0.969521 | 0.89709 |
| 11-bm | 56.17 | 2.89 | 0.779755 | 29.63 | 0.73 | 0.972338 | 0.9047 |
| 11-tm | 47.78 | 2.82 | 0.783315 | 28.59 | 0.71 | 0.972112 | 0.934333 |
| 12-bf | 58.43 | 2.64 | 0.817714 | 59.46 | 0.79 | 0.970899 | 0.905025 |
| 12-tf | 46.87 | 2.66 | 0.823344 | 84.98 | 0.82 | 0.965004 | 0.944747 |
| 13-bm | 52.52 | 2.52 | 0.821301 | 95.77 | 0.89 | 0.964482 | 0.907044 |
| 13-tm | 45.36 | 2.71 | 0.816527 | 26.88 | 0.71 | 0.974257 | 0.911623 |
| Average | 49.18 | 2.79 | 0.7942 | 38.66 | 0.73 | 0.9724 | 0.91979 |

FIG. 24 illustrates extracting the main path of the entire force. Part (a) illustrates the original entire force diagram. Part (b) illustrates the force diagram with main paths.

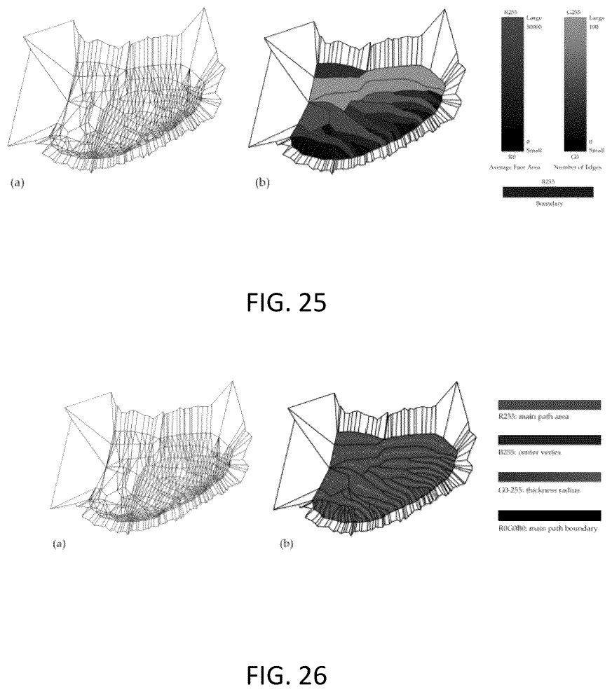

FIG. 25 illustrates the main path combining the vertexes information. Part (a) illustrates the original entire force diagram. Part (b) illustrates the force diagram with main paths and pixel values. In the first representation of the main path, the external force geometry is directly identified as the main path, while the internal force geometry is as the following workflow: 1) starting from the left root point, as clockwise, the script traverses all horizontally continuous lines from each point on the boundary of the internal force geometry until it reaches a point that is previously reached or it reaches a point on the boundary; 2) all the lines that are traversed together split the internal force boundary into several areas; 3) for each area, it contains polygons from the entire force diagram, the average area of all the polygons in the area is mapped as values in the R channel of an image, the number of lines in the area is mapped as values in the G channel of the same image, while the main paths are marked in the B channel of that image; 4) the force diagram with main paths is then generated as a color-coded image (FIG. 25, part (b)) showing a simplified version of the entire force diagram image (FIG. 25, part (a). With this main path extraction process, we generate an intermediate image between the force boundary image and the entire force diagram image, which helps increase the efficiency and accuracy in the following machine learning process.

In the second representation of the main path (FIG. 26), the R channel with a value of either 0 or 255 represents the regions of each main path, the B channel with a value of either 0 or 255 represents the existing of the middle points, and the G channel represents the length of the corresponding lines in the force geometry if the value in the B channel shows an existing middle point in that pixel. If the values in the R, G, and B channels are all 0, the pixel is regarded as the Black channel, which represents the boundaries of the main path. This force main path can store both the pixel-based information of the boundaries of the main path, and the vector-based geometric information of the force lines.

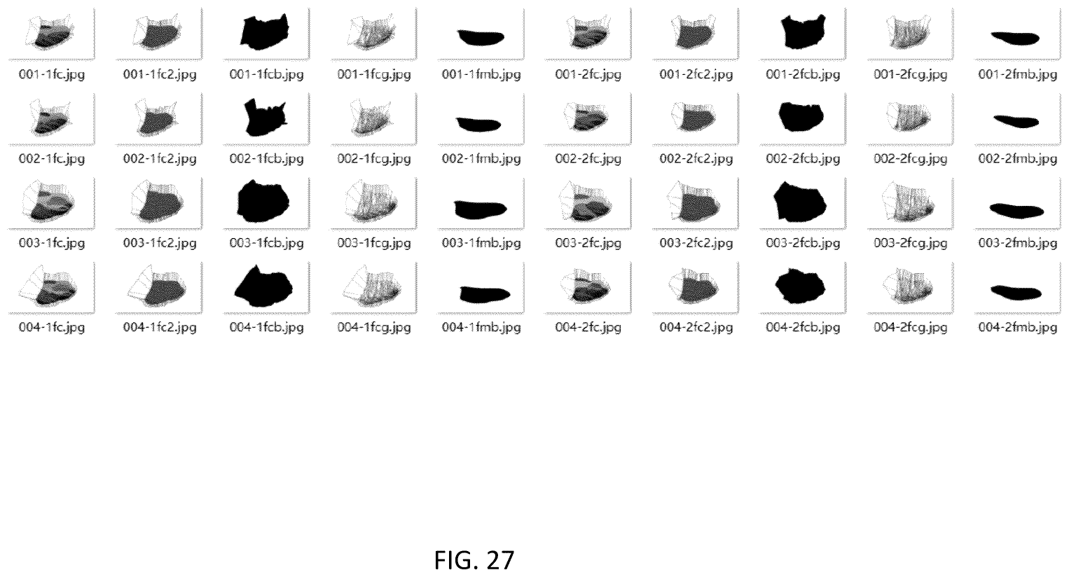

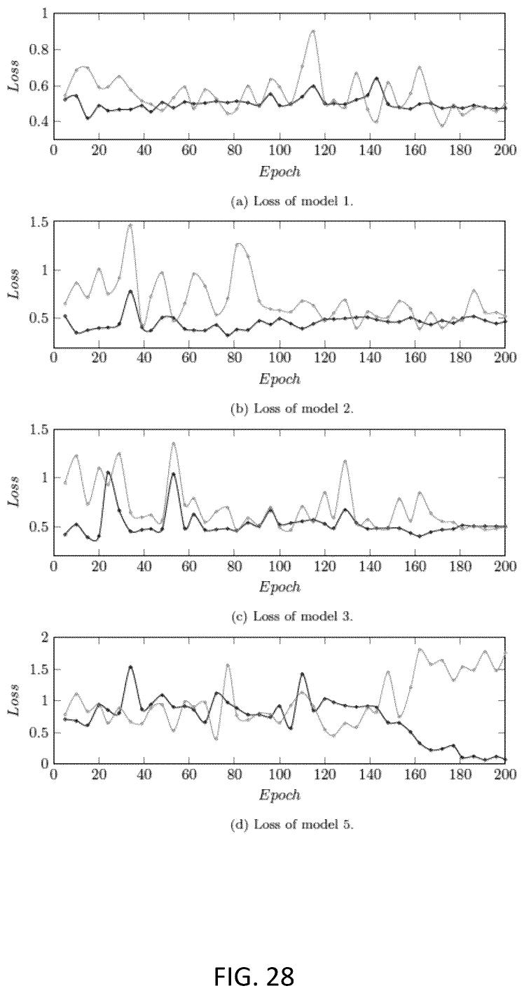

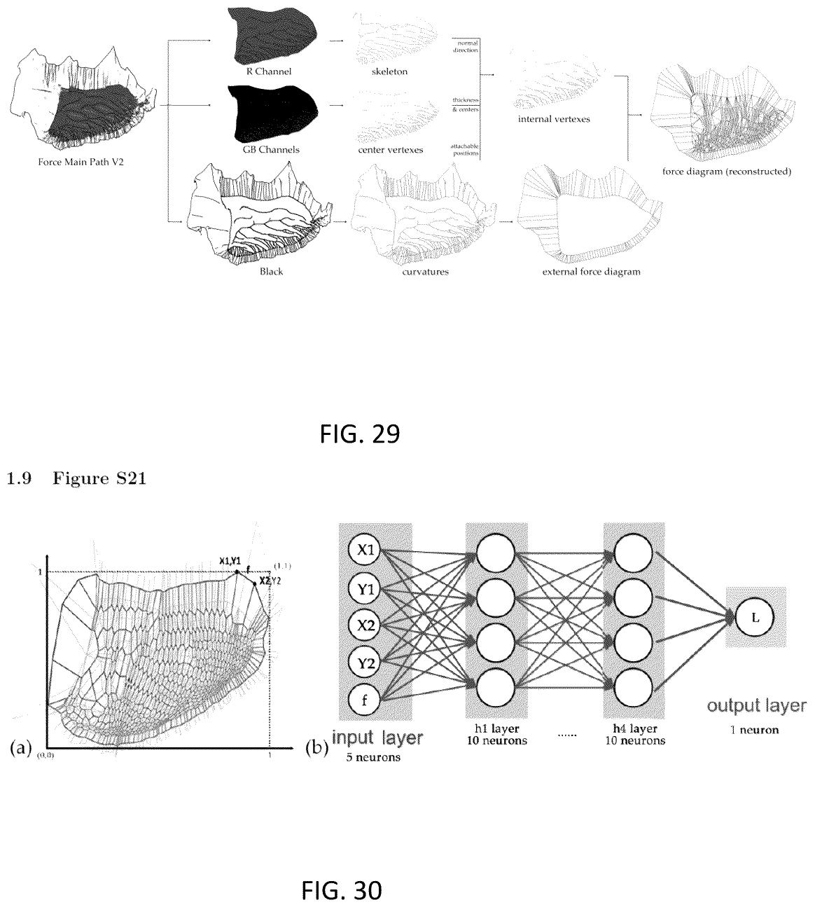

FIG. 27 illustrates examples of the machine learning model 1, 2, 3, and 5 dataset (25 pieces*5 images*7 rotating copies, 1000*600 pixels) (21 pieces as training set, 4 pieces as testing set). FIG. 28 includes graphs illustrating the loss of the generator (orange) and the discriminator (blue). FIG. 29 illustrates post-processing to generate the force geometry of machine learning method 2.

Technically, the data format for the machine learning process is image-based, thus the image-to-image machine learning technique, generative adversarial network (GAN), is applied in the learning and generating tasks. In the neural network structure of the generator in the GAN, an input image is proceeded into an output image with the same size using convolutional, residual, and deconvolutional layers. Another neural network, the discriminator, works to distinguish the image generated by the generator from the ground truth image. The generator feeds forward the generated result to the Discriminator, while the discriminator feeds back the loss and gradient to the generator. Thus, the generator is trained to generate the fake images closer to the ground truth, while the discriminator is trained to tell distinguish the fake images from the ground truth images. The two networks compete with each other, and thus this system is described as being adversarial.

FIG. 27 shows the dataset used in the training process. We have proceeded with the dataset of 25 pieces of dragonfly wings, and there are five images for each piece (form boundary, force boundary, force main path version 1, force main path version 2, and force diagram). We use the first 21 pieces as the training set and the left 4 pieces as the testing set. To increase the size of the dataset, we apply image augmentation techniques to rotate the training images with −15, −10, −5, 0, 5, 10, 15 degrees.

In the training process, we use the same set of hyperparameters for all three models. The width of the images is 1000 pixels, and the height of the images is 600 pixels. The learning rate is constantly 0.0002 for the first 140 training epochs, and it is decreasing to 0 for the rest 60 training epochs. The training time cost for each model is 7.49 hours for a Tesla V100 computing GPU. FIG. 28 shows the loss of the generator and the discriminator during the training process of the three models. The changing of the peaks and valleys indicates that the training was successful.

For the machine learning method 2, post-processing is applied to the generated image to reconstruct the force geometry (FIG. 29). To be specific, the R channel is firstly separated and the skeleton geometry is extracted using sknw [2] in Python. Second, the middle points are recognized from the G and B channels. The main path boundaries are extracted from the black pixels, from which the external force geometry is reconstructed. Next, the internal vertexes are inferred from the skeleton geometry, middle points, and the main path boundaries. Finally, the internal triangulation is generated based on the internal vertexes in Rhino [3], and the entire force geometry is combined from the internal and the external force geometries. The final geometry should be a series of closed polygons that together becomes a convex network to meet the requirement of our graphic statics method.

FIG. 30 illustrates details of the ANN. Part (a) illustrates ANN dataset preparation. Part (b) illustrates ANN structure. The ANN dataset contains 86412 pieces of data from 43206 edges in the dragonfly wing dataset, from which 82806 pieces are used as the training dataset and 3606 pieces are used as the testing dataset. All values are normalized into the range of 0 to 1 for better training. The ANN structure contains 4 hidden layers with 10 hidden neurons for each layer, 5 input neurons, and 1 output neuron (FIG. 30). We use Sigmoid function (Eq. 5) as the activation function and the mean squared error (MSE) function (Eq. 6) as the loss function. The training process of the ANN takes a CPU-only laptop several minutes to complete, with an accuracy of 97.8% for the testing dataset. Therefore, with the predicted edge lengths, the structural form is generated. FIG. 3 shows the final workflow of the two methods.

$$\hat{y} = Sigmoid ( w * x + b ) = \frac{1}{1 + {e}^{- ( w ⋆ x + b )}} \qquad ( 5 )$$

$$Loss ( y , \hat{y} ) = \frac{1}{n} {\sum }_{i = 1}^{n} {( {y}_{i} - {\hat{y}}_{i} )}^{2} \qquad ( 6 )$$

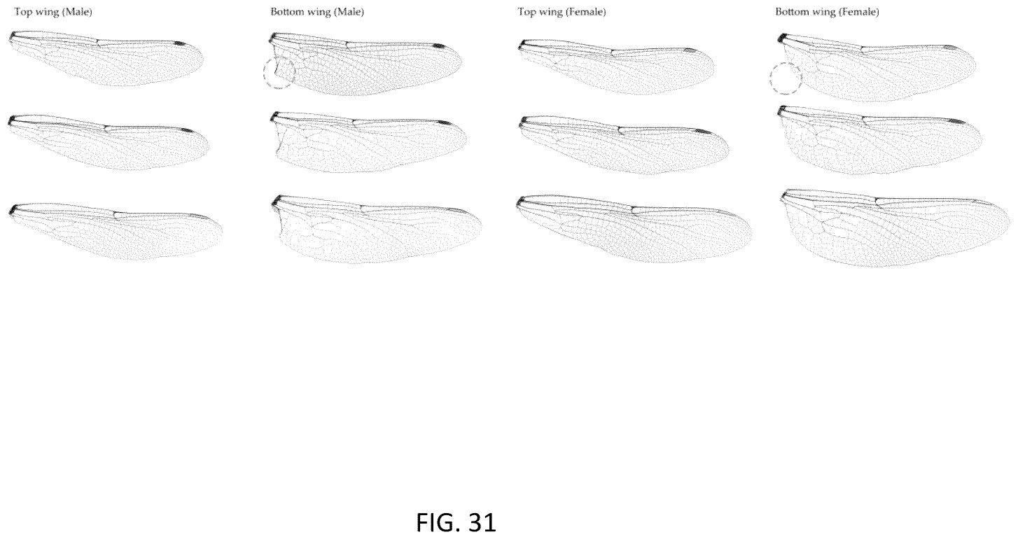

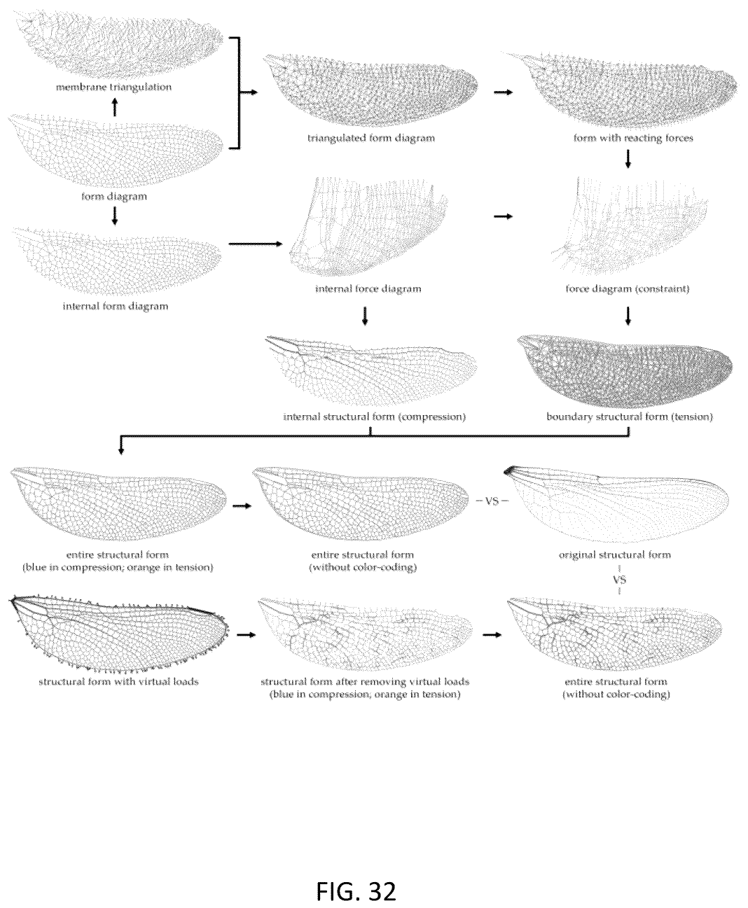

FIG. 31 illustrates categories of different dragonfly wings. FIG. 32 explores the actual loading scenario of the dragonfly wing. We abstract the membrane and the boundary ring as triangulated members, which can only bear the tension force. By merging the tension-only membrane and boundary ring with the compression-only internal structure, the combined structural form shows a complex compression-and-tension pattern. Further, we develop an algebraic solution to calculate the tension and compression status after removing the virtual loads. It also shows a complex compression-and-tension pattern.

From the above-described experiments, we can find the capability of machine learning in generating the force diagram. Our force diagram is an abstract of the loading scenario, and from the perspective of a form finding tool for designers, it provides a solution with a certain degree of accuracy. However, as we mentioned before, the actual loading scenario is not exactly correct for the force diagram, the entire dragonfly wing might be a compression-tension-mixed situation, in which some members are bearing compression forces but some are in tension. One of the preconditions of our graphic statics method is that the entire system is either fully in compression or fully in tension. Although our final result shows the match of the generated structural form and the real structural form, the actual loading scenario is still unclear. Therefore, besides the success of our method as a form finding tool, we want to open the discussion of the actual loading scenario to see whether we can reach a conclusion of the real force pattern.

Therefore, we design the following experiment to explore the loading scenario (FIG. 32). First, the dragonfly wing not only contains the internal funicular members, but also contains the membrane and the boundary ring, which can only bear tension forces. Therefore, we generate the triangulation of each cell in the form diagram as an abstraction of the membrane. Second, since we do not know whether each internal member is actually in compression or in tension, besides the compression-only force diagram for the internal members, we assume that the internal members might also bear tension force. Also, as the reacting forces for the compression-only internal forces, the boundary members of the dragonfly wing should also bear tension. Thus, the internal members, the triangulation of the membrane, the boundary ring, and the reacting forces as additional geometries can be merged as a tension-only form, which works together with the compression-only internal form.

With this new tension-only form, we apply our graphic statics method to generate the force diagram, under the condition that the reacting forces should be the same with the corresponding members in the internal force diagram, thus we use the force boundary of the internal force diagram as the boundary constraint for the tension-only force diagram. This operation ensures the reacting forces from the compression-only form and the tension-only form match with each other, while the rest members in the tension-only form can be transformed into the corresponding force diagram. However, noted that the Geometric Degree of Freedom (GDoF) [4] of the tension-only form diagram is 956 (larger than 0), which means the structure is very indeterminate and there are infinite number of force diagrams that can be generated and satisfy the graphic statics rules. Therefore, the generated force diagram only represents one of the solutions, and the actual situation can be different and more complex.

Last, we map the edge lengths in the force diagram to the structural thickness in the form diagram, and generate the structural form for the tension-only part. Then we combine the two structural forms together and generate the entire structural form, which shows a mixed condition of the tension and compression patterns. However when we compare the combined structural thickness with the real structural thickness, they clearly do not match. To verify this phenomenon, we further also develop an algebraic solution to calculate the tension and compression status after removing the virtual loads. The result also shows a mixed condition of the tension and compression patterns. And the generated structural thickness does not match the real wing.

Therefore, we regard this result as a conclusion that the actual loading scenario and the force pattern are more complex than we thought, it is hard to identify the compression-and-tension status of each structural member in the dragonfly wing. Therefore, we conclude that the actual force diagram with the real loading scenario is uncertain and unable to be learned by machine learning. The previous force diagram which abstractly represents the structural thickness for machine learning is suitable to reveal the morphological properties of the dragonfly wing, as that our method is a form finding tool for designers.

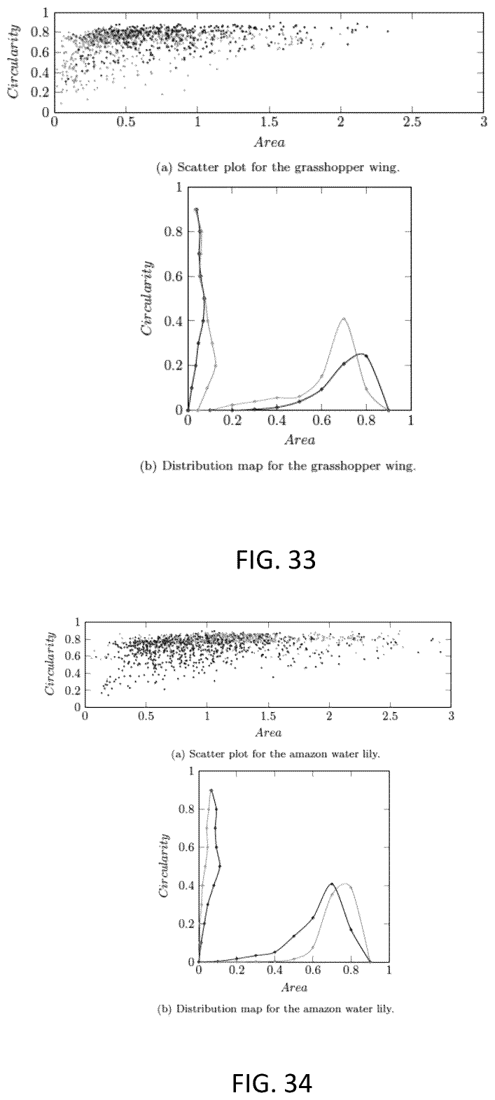

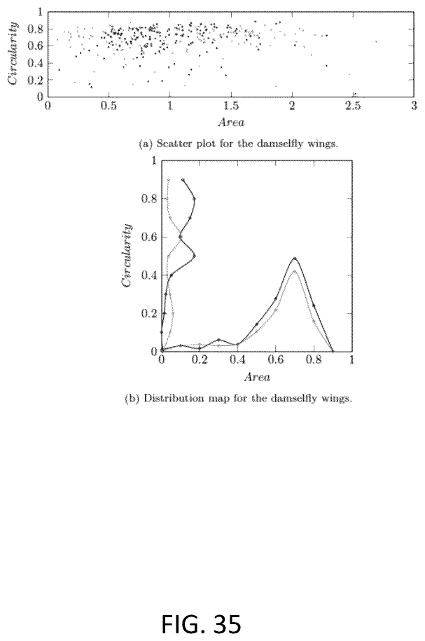

FIG. 33 is a plot of the area and the circularity of each polygon for the real grasshopper wing (orange) and the generated grasshopper wing (blue). FIG. 34 is a plot of the area and the circularity of each polygon for the real amazon water lily (orange) and the generated amazon water lily (blue). FIG. 35 is a plot of the area and the circularity of each polygon for the real damselfly wings (orange) and the generated damselfly wings (blue).

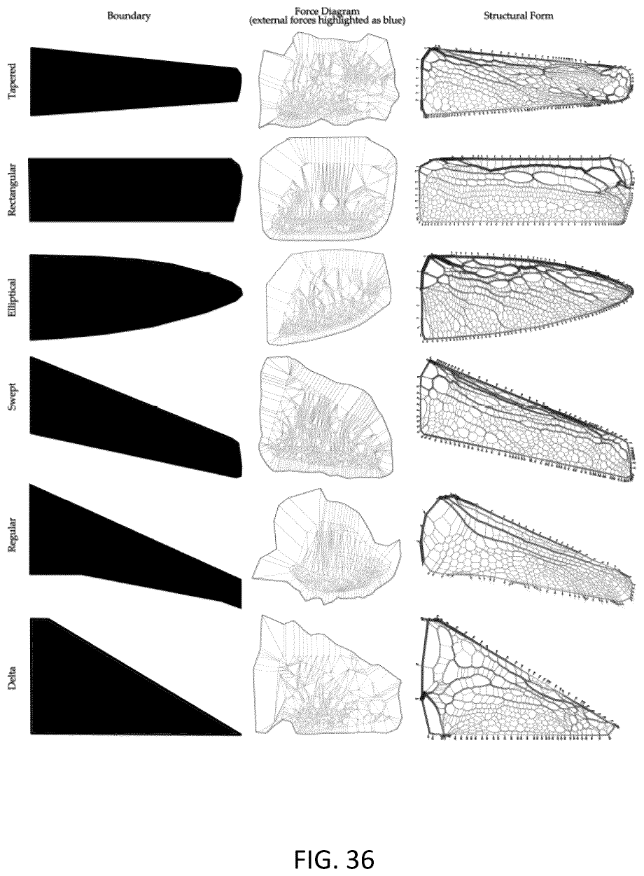

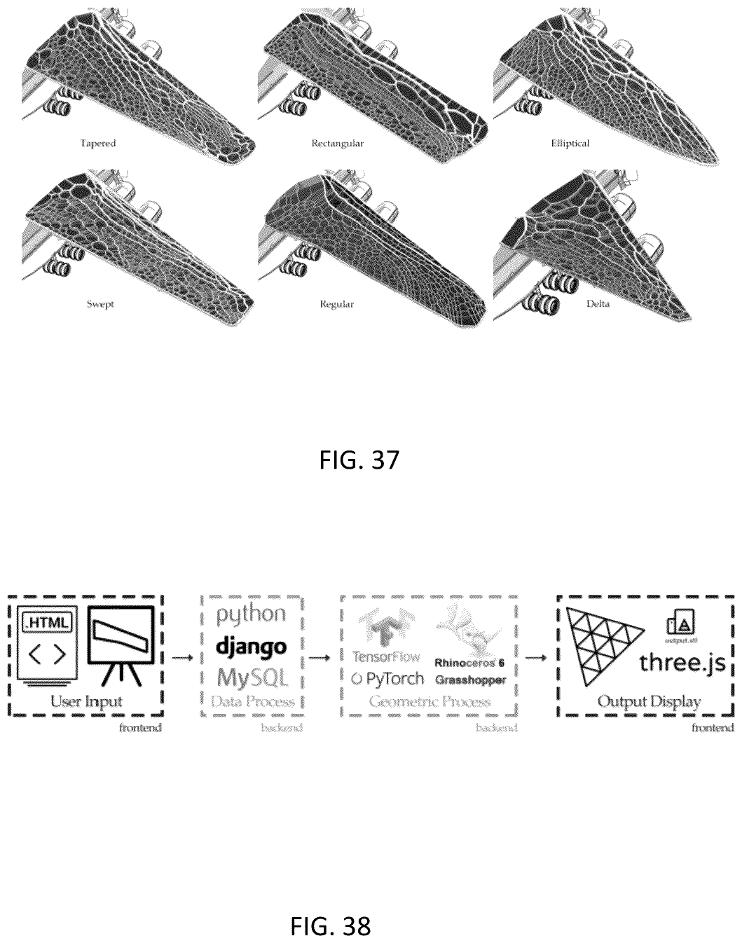

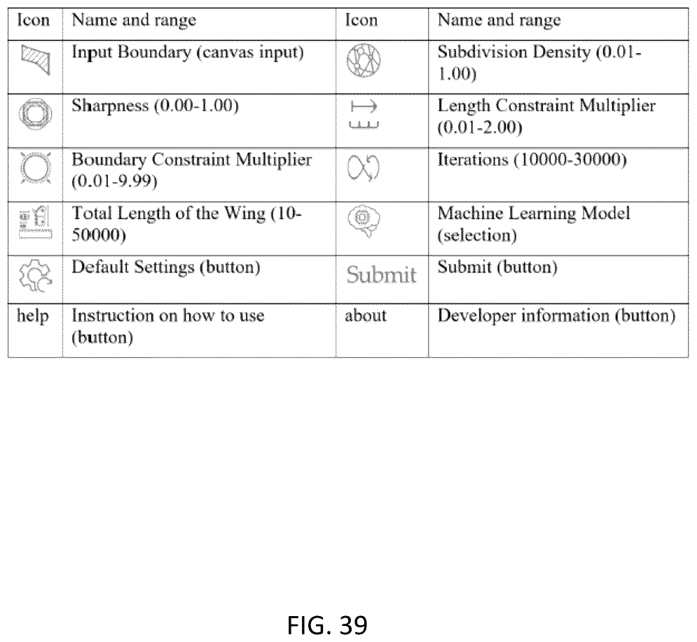

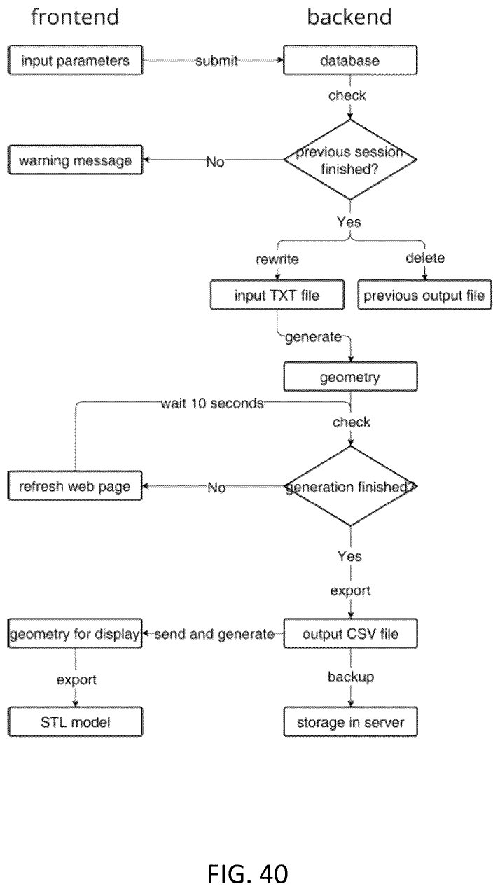

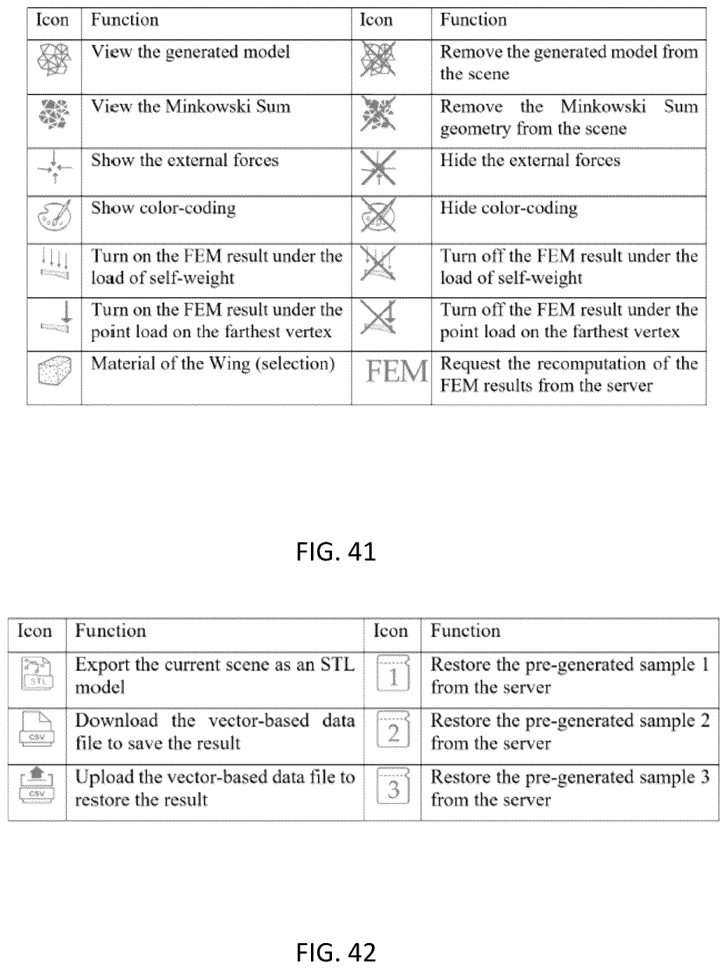

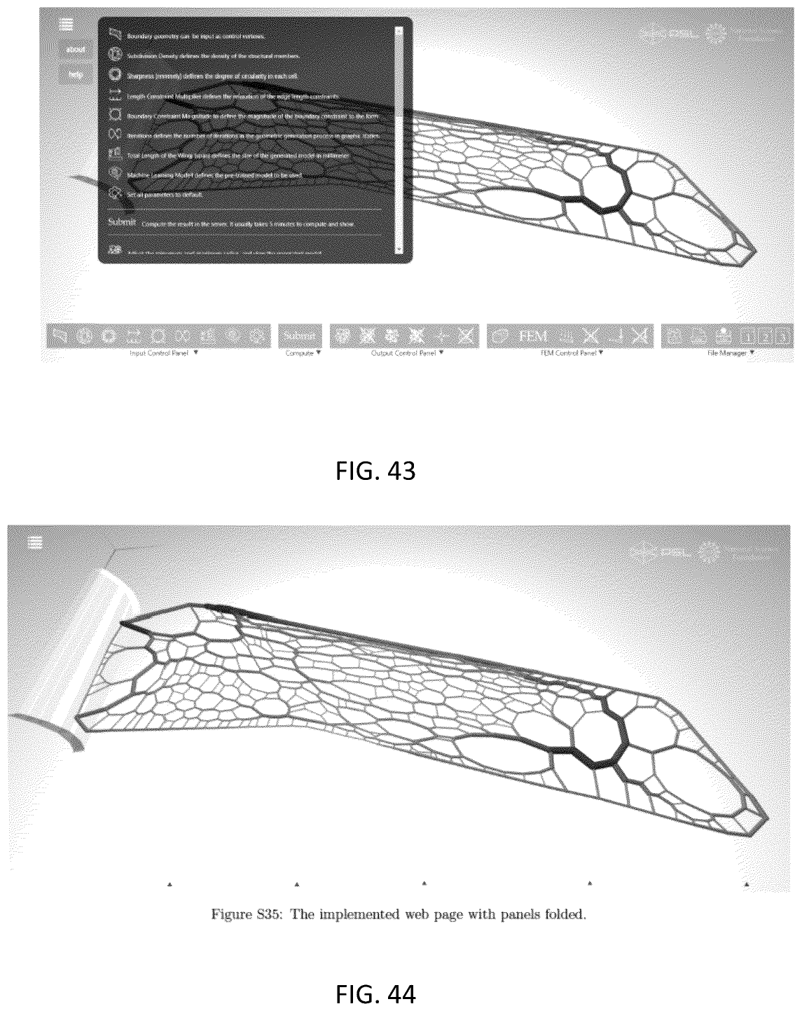

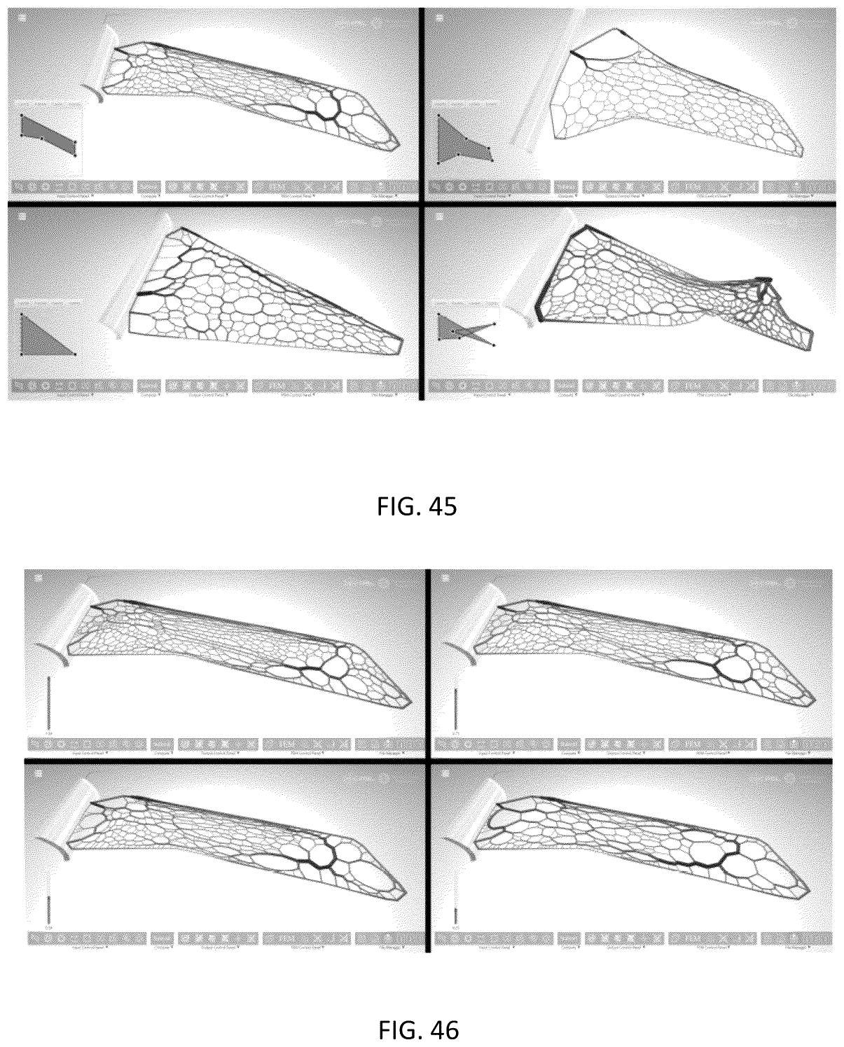

FIG. 36 illustrates boundaries, force diagrams, and form diagrams of the generated airplane wings. (The virtual loads are highlighted as green.) FIG. 37 illustrates renderings of the generated airplane wings. FIG. 38 illustrates the workflow and data flow of the web tool. FIG. 39 illustrates control parameters and functional buttons in the user input panel and the compute panel. FIG. 40 illustrates the workflow in the back end and the front end of the server after the user submits the input parameters. FIG. 41 illustrates functional buttons in the output control panel and the FEM control panel. FIG. 42 illustrates functional buttons in the file manager panel. FIG. 43 illustrates the implemented web page with panels unfolded. FIG. 44 illustrates another view of the implemented web page with panels folded. FIG. 45 illustrates generated structures with different user-input boundaries.

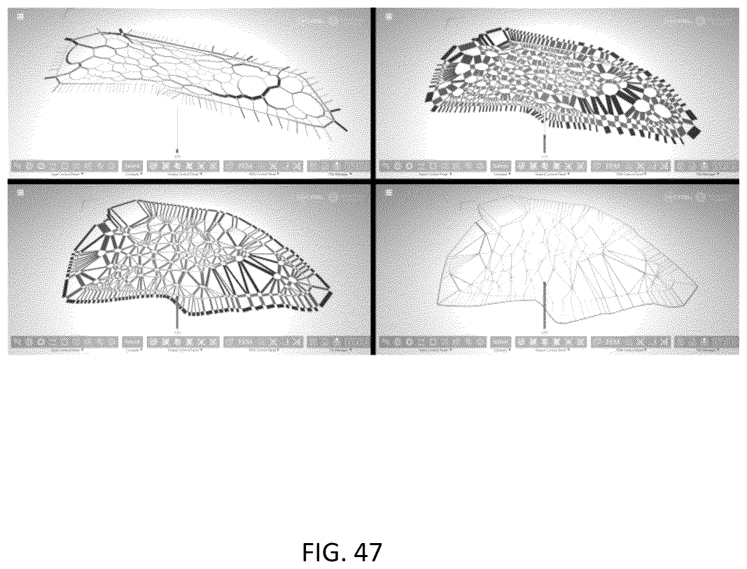

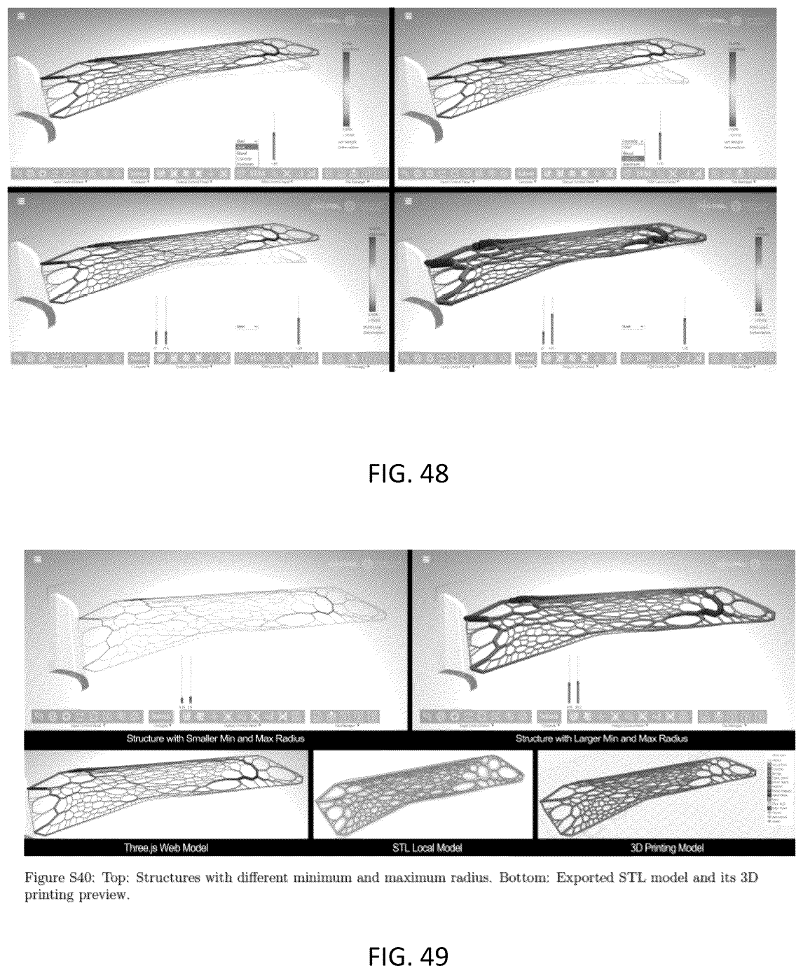

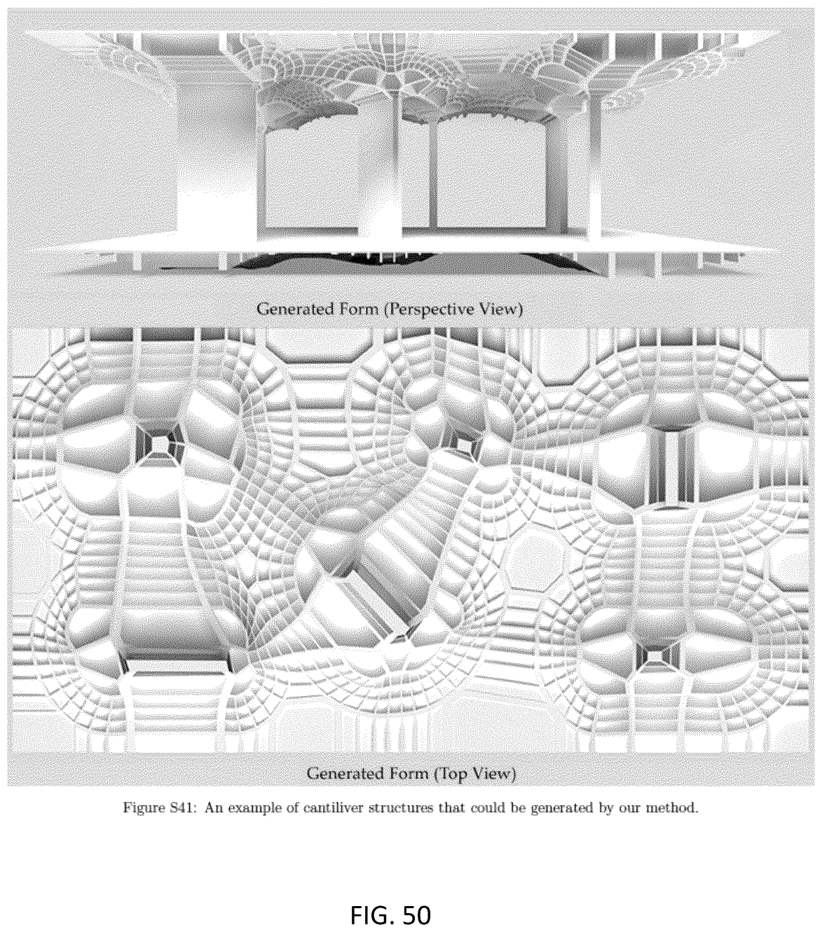

FIG. 46 illustrates generated structures with different subdivision densities. Top left: SD=1.0. Top right: SD=0.75. Bottom left: SD=0.5. Bottom right: SD=0.25. FIG. 47 illustrates generated Minkowski Sum with different stage indicators. Top left: MSI=0.05. Top right: MSI=0.35. Bottom left: MSI=0.65. Bottom right: MSI=0.95. FIG. 48 illustrates FEM analysis results with different loading scenarios, materials, and structural thickness. Top left: self-weight load with steel material. Top right: self-weight load with concrete material. Bottom left: point load with steel material. Bottom right: point load with steel material and larger structural thickness. FIG. 49 illustrates (top) structures with different minimum and maximum radius and (bottom) an exported STL model and its 3D printing preview. FIG. 49 illustrates an example of cantilever structures that could be generated by our method.

We developed a web-based tool that accepts user inputs and feedback generated structures. The web tool is implemented as an online resource and open for designers to visit as a web page. Meanwhile, a local server proceeds the input data, generates the output structure, and sends the model file to be displayed on the web page. With this web tool, designers can easily adjust the input parameters and boundary conditions, and obtain the structure model online, without going through the complex local computing process.

To be specific, FIG. 38 shows the workflow of the web tool, which contains the frontend and backend. It follows four steps: 1) The user inputs the boundary and parameters in the web page, and HTML and JavaScript [5] transform the data from Canvas [6] into a formatted database; 2) The server stores and proceeds the data [7,8], and updates an indicator file; 3) The geometric components [3,9] and the machine learning components [10,11] in the server work together to generate the structural model as CSV file, and send it back to the web page; 4) the web page [12] displays the model, and allows the user to generate and download the STL file.

First, the web page should receive the input boundary and parameters from the user. FIG. 39 shows the icons, names, ranges, and buttons in the “Input Control Panel”. The boundary is defined as a closed polygon of several vertexes. The user can select the number of vertexes and adjust the positions of each vertex by dragging them on the canvas. The boundary vertexes are transformed into numeric values based on their coordinates. Noted that, the first line in the boundary is defined as the anchor position, thus additional marks and geometries are drawn and shown to the user to identify the anchor. Besides, the “Input Control Panel” also includes parameters that are defined as numeric values. A set of six parameters can be input from the user and sent to the server. To be specific, “Subdivision Density” defines the density of the structural members. By increasing it, more members will be generated with a longer time cost. “Sharpness” defines the upper and lower bounds of the length constraint for each edge. Increasing it will give more freedom to the geometric generation process in graphic statics. “Length Constraint Multiplier” defines the relaxation of the edge length constraints. Increasing it will cause more rectangular cells than circular cells. “Boundary Constraint Magnitude” defines the magnitude of the boundary constraint to the form. Increasing it will make the structure attach closer to the boundary. “Iterations” defines the number of iterations in the geometric generation process in graphic statics. Increasing it will generate a more accurate structure but with a longer time. “Total Length of the Wing” defines the size of the generated model in millimeter. Last, the user can select the machine learning model of different species, the default is set as the dragonfly wing model.

It should be noted that, the web page will restore the input parameters when the user successfully submitted the last time, thus the user can more easily adjust the parameters. There is a button “Default Settings” by clicking it, the input parameters will be set as the default values. If a new user does not understand the meaning of each parameter, he/she can move the mouse cursor to the button of each parameter to see its name and click the “help” or “about” button to see the detailed instructions.

When finishing adjusting the six input parameters, the user can click the “Submit” button in the “Compute” panel to send the first set of input parameters to the server. FIG. 40 shows the algorithm in the back end and the front end of the server after the user submits the input parameters. First, in order to avoid duplicated submissions from multiple users before the server completely responds to the current request, an indicator value in the server is first loaded by the web page. If it indicates that a request is being proceeded, a warning message will be shown to the user when he/she clicks the “Submit” button, and no values will be submitted to the server. Besides, the entire generation process in the server usually takes three to seven minutes. The web page will be automatically refreshed every 10 seconds until it receives the result from the server.

When the server finishes the generation process, it will send back a CSV file to the web page, which contains the geometric information of the generated structure, the graph information for implementing the Minkowski sum, and the numeric information of the FEM analysis. The geometric information contains the coordinates of the start and end points of each edge, as well as its corresponding force magnitude. The graph information stores the connectivity matrix of the form and the force diagrams. The FEM analysis result contains the deformation magnitude for each edge in the structure.

Next, when the web page receives the data file, the user can choose a different display mode in the “Output Control Panel” and “FEM Control Panel” (FIG. 41) to turn on or off the generated model and the Minkowski Sum. Also, the user can turn on or off the FEM results under the load of self-weight or under the point load in the farthest vertex.

In the case of the normal display mode, the web page regenerates the structural members according to the information from the file and the second set of the user input parameters of the minimum radius and the maximum radius. An additional transparent box geometry is shown to indicate the anchor of the structure. The user can control the camera with the mouse in the main display window to better view the generated model. The generated 3D model is displayed on the web page with pre-set lighting environment. However, to reduce the computational load from the local device, the shadow is represented as a series of static geometries on the ground with gray lines. The color setting for the main geometry keeps constant with that in PolyFrame. In the display control panel, the user can also change to turn on or off the display of the external forces.

In the case of the Minkowski Sum mode, the web page reads the user input of the Minkowski sum indicator (MSI) and calculates the corresponding status in the form-to-force transformation. The graph information in the feedback file contains the following items: 1) the coordinates of the vertexes in the form diagram; 2) the index of neighbor cells of each cell in the force diagram; 3) the index of the shared edges in the neighbor cells of each cell in the force diagram; 4) the index of edges in each cell; 5) the coordinates of the start and end points of each edge in the force diagram. By scaling the cells in the force diagram with the MSI value and moving them to each corresponding vertex in the form diagram, each edge in the force diagram will become an area with thickness. Therefore, with a gradually-changed MSI value from 0 to 1, the areas shift from the edges in the form diagram to the edges in the force diagram, thus showing the transformation between the form and force. Still, the user can turn on or off the external forces in the Minkowski Sum mode.

For the FEM analysis, Karamba [13] is used to calculate the deformation of edges based on the user input of the span and the material of the structure. Applicable materials include steel, wood, concrete, and aluminum, and the material property is embedded in Karamba. We provide two types of loading: 1) self-weight loading for all vertexes; 2) point loading for the farthest vertex to the anchor with the magnitude of half of the self-weight. In the CSV data file, the FEM analysis part includes the following information for each edge: 1) coordinates (x,y,z) for the start and end points (deformation in Z axis included); 2) color-coding value (R,G,B). The user can adjust the multiplier in the front end to increase or decrease the deformation magnitude, and view the color-coded edges and color scales. When the user changes the material setting or the structural thickness, a recomputation request can be sent to the server and the FEM results will be updated in around ten seconds.

In addition, to better help users restore the previously generated results, in the “File Manager” panel (FIG. 42), users can download the data as a CSV file and save it on their local computer. If the user inputs an email address when submitting a request to the server, when the computation is finished, the server will send an email to the user with the CSV data file attached. By uploading the file to the web page, users can restore the input parameters, the output structure, the Minkowski sum geometry, and the FEM analysis results. Restoring the previous result only requires the local computer from the user, thus it is an offline process and does not require a connection to the server. Also, the user can export and download the STL file for 3D printing or other purposes.

Therefore, with this web page implementation http://www.ai-gs.com/frontend/DFW-GH.html [14], users even without much knowledge of machine learning and graphic statics could easily generate lightweight and high-performance structures within given boundaries. FIG. 43 shows the web page with control panels unfolded, and FIG. 44 shows the web page with control panels folded. The user can freely decide to fold or unfold each panel to better balance the UI and the model display.

Next, several cases are generated and shown using our web tool. The user can either submit multiple requests to our backend server to generate structures with different input-related parameters or adjust the output-related parameters in the frontend to view and export results.

In the first case (FIG. 45), structures with different input boundaries are generated. The user can select the number of control points in the input boundary, and drag the points to adjust their positions. Even if the user inputs an invalid boundary such as crossing curvatures, our geometric script will merge it into a pixel-based black-and-white image, and send the image to machine learning models. In addition, the user is not required to input a wing-like boundary. As long as the anchor is on the left, any cantilever structure can be generated with the input boundary, which contains the features of dragonfly wings.

The second case shows one example of controlling other input parameters such as the subdivision density (FIG. 46). Among the input parameters, the subdivision density is the most important one since it directly controls the complexity of the generated structure. A smaller subdivision density can significantly simplify the structure while keeping the features of dragonfly wing patterns. In our recent research, we found that simplifying the structure to a certain degree would increase the structure performance, and make it easier to fabricate in the real world. Thus, the user can consider the fabrication ability and adjust the subdivision density. Other parameters such as sharpness and iterations can also greatly affect the generated result, but changing the input parameters requires a re-computation from our server and it usually takes around five minutes to respond.

Besides changing the input parameters, the user can also adjust the output display modes and the related indicators to show or hide the generated structures and the analytical results. FIG. 47 shows the case of the Minkowski sum in different stages with different values of the indicator. The indicator defines position in percentage of the current Minkowski Sum in the form-to-force transformation. The result is closer to the form diagram with a smaller value of the indicator, while it is closer to the force diagram with a larger value of the indicator. The user can adjust the value of the indicator and view the smooth transformation from the form to the force.

Also, FIG. 48 shows the FEM results under different loading scenarios and materials. As mentioned, in the geometric mechanism of our server, we provide the FEM results of the deformation under the self-weight or a point load. The user can decide to show none/one/both of them by clicking the corresponding buttons in the output control panel, or hide the main structure to better compare the FEM results. The color-coded scale is also shown on the right of the web page when the corresponding FEM result is shown. The scale includes the minimum and maximum values of the percentage of deformation compared with the span, and the real values of the deformation in millimeter. When keeping the deformation multiplier constant, the user can also directly compare the FEM results from different structures.

The final case shows the application of our web tool in exporting the result to other platforms for various purposes. In the normal display mode, the user can adjust the minimum and the maximum radius to control the range of the thickness for edges, and export the structure as an STL model (FIG. 49). The exported STL model can be imported to a variety of platforms, including modeling software for further analysis and 3D printing software for digital fabrication. Therefore, our web tool completes the logic of loop by accepting the user input and exporting the generated result back to the user.

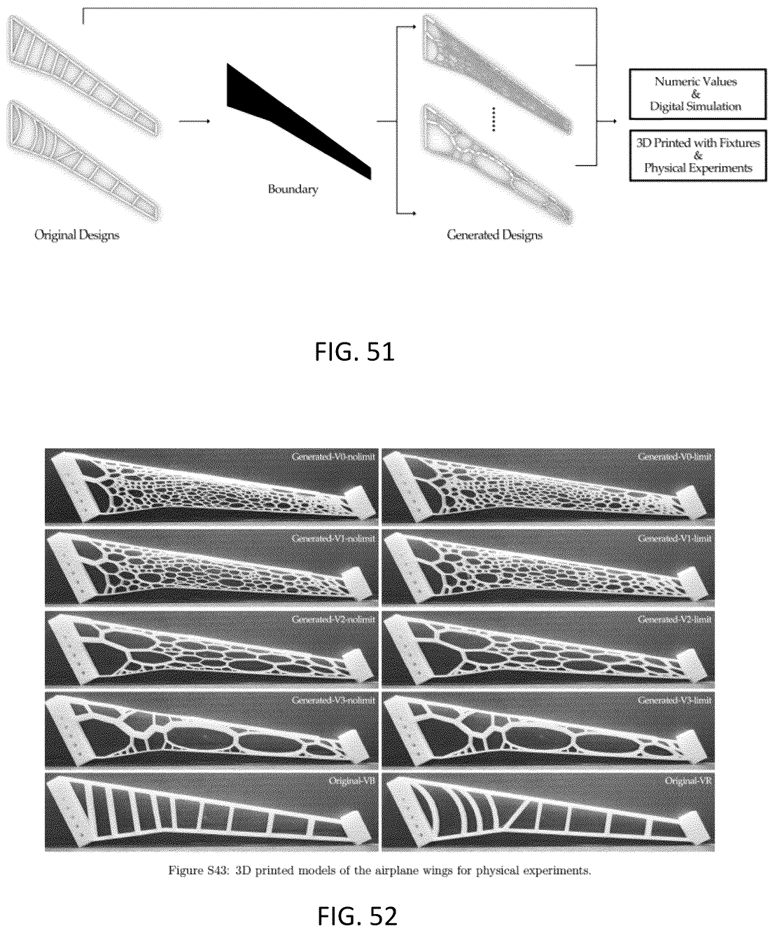

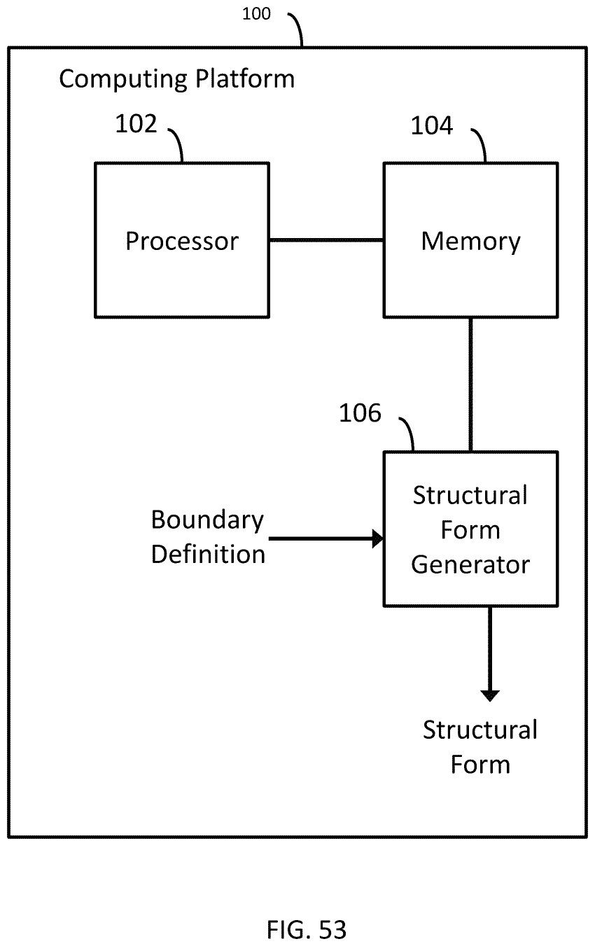

FIG. 51 illustrates design process of the airplane wings for testing. FIG. 52 illustrates 3D printed models of the airplane wings for physical experiments.

FIG. 53 illustrates and example of a computing platform on which a trained structural form generator as described herein may be implemented. Referring to FIG. 53, a computing platform 100 includes at least one processor 102 and a memory 104. A structural form generator 106 may be implemented using computer executable instructions stored in memory 104 and executed by processor 102. Structural form generator 106 may be a trained adversarial neural network as described herein that receives a boundary definition as input and that generates a force diagram and a structural form as output. The structural form may be a diagram that shows polygons or other structures used to distribute force across the structure.

The disclosure of each of the following references is incorporated herein by reference in its entirety.

### REFERENCES

[1] John Tann, Dragonfly wings, 2014, Https://www.ickr.com/photos/31031835@N08.
[2] Image-py/sknw: build network from skeleton image (2d-3d), https://github.com/Image-Py/sknw, 2021, (Accessed on Aug. 5, 2021).
[3] Rhino-rhinoceros 3d, https://www.rhino3d.com/, 2021, (Accessed on Aug. 5, 2021).
[4] M. Akbarzadeh, M. Hablicsek, In Design Modelling Symposium Berlin. Springer, 2019 3{17.
[5] Javascript.com, https://www.javascript.com/, 2022, (Accessed on Mar. 26, 2022).
[6] Html canvas, https://www.w3schools.com/html/html5_canvas.asp, 2022, (Accessed on Mar. 26, 2022).
[7] The web framework for perfectionists with deadlines|django, https://www.djangoproject.com/, 2022, (Accessed on Mar. 26, 2022).
[8] Mysql, https://www.mysql.com/cn/, 2022, (Accessed on Mar. 26, 2022).
[9] Grasshopper-algorithmic modeling for rhino, https://www.grasshopper3d.com/, 2022, (Accessed on Mar. 3, 2022).
[10] Tensorow, https://www.tensorflow.org/, 2022, (Accessed on Mar. 26, 2022).
[11] Pytorch, https://pytorch.org/, 2022, (Accessed on Mar. 26, 2022).
[12] Three.js javascript 3d library, https://threejs.org/, 2022, (Accessed on Mar. 26, 2022).
[13] Karamba3d { parametric engineering, https://www.karamba3d.com/, 2022, (Accessed on Apr. 29, 2022).
[14] Wing structure generator|psl, http://www.ai-gs.com/frontend/DFW-GH.html, 2022, (Accessed on Apr. 7, 2022).

The scope of the present disclosure includes any feature or combination of features disclosed in this specification (either explicitly or implicitly), or any generalization of features disclosed, whether or not such features or generalizations mitigate any or all of the problems described in this specification. Accordingly, new claims may be formulated during prosecution of this application (or an application claiming priority to this application) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A method comprising:
receiving a definition of a boundary of a target structure;
generating an output force diagram using the boundary and one or more machine-learning models trained on at least one force diagram of an internal network of a natural structure; and
generating a structural form within the boundary using the output force diagram.

2. The method of claim 1, wherein receiving the boundary comprises receiving an image of the boundary, and wherein the one or more machine-learning models comprise at least one image-based neural network configured to generate the output force diagram from the image of the boundary.

3. The method of claim 1, wherein the one or more machine-learning models comprise at least one vector-based neural network configured to determine geometric information based on the boundary.

4. The method of claim 1, comprising generating the at least one force diagram using graphic statics and the internal network of the natural structure.

5. The method of claim 4, comprising generating a form diagram that represents the form of the internal network of the natural structure.

6. The method of claim 5, comprising training the one or more machine-learning models using the force diagram and the form diagram.

7. The method of claim 1, comprising determining a geometry of a force network for the natural structure by iteratively rotating the edges of the force diagram to minimize a deviation parameter to determine a solution of the force diagram within a predefined tolerance.

8. A system comprising:
at least one processor; and
a structural form generator implemented on the at least one processor and configured to perform operations comprising:
receiving a definition of a boundary of a target structure;
generating an output force diagram using the boundary and one or more machine-learning models trained on at least one force diagram of an internal network of a natural structure; and
generating a structural form within the boundary using the output force diagram.

9. The system of claim 8, wherein receiving the boundary comprises receiving an image of the boundary, and wherein the one or more machine-learning models comprise at least one image-based neural network configured to generate the output force diagram from the image of the boundary.

10. The system of claim 8, wherein the one or more machine-learning models comprise at least one vector-based neural network configured to determine geometric information based on the boundary.

11. The system of claim 8, the operations comprising generating the at least one force diagram using graphic statics and the internal network of the natural structure.

12. The system of claim 11, the operations comprising generating a form diagram that represents the form of the internal network of the natural structure.

13. The system of claim 12, the operations comprising training the one or more machine-learning models using the force diagram and the form diagram.

14. The system of claim 8, the operations comprising determining a geometry of a force network for the natural structure by iteratively rotating the edges of the force diagram to minimize a deviation parameter to determine a solution of the force diagram within a predefined tolerance.

15. A non-transitory computer readable medium storing executable instructions that when executed by at least one processor of a computer control the computer to perform operations comprising:
receiving a definition of a boundary of a target structure;
generating an output force diagram using the boundary and one or more machine-learning models trained on at least one force diagram of an internal network of a natural structure; and
generating a structural form within the boundary using the output force diagram.

16. The non-transitory computer readable medium of claim 15, wherein receiving the boundary comprises receiving an image of the boundary, and wherein the one or more machine-learning models comprise at least one image-based neural network configured to generate the output force diagram from the image of the boundary.

17. The non-transitory computer readable medium of claim 15, wherein the one or more machine-learning models comprise at least one vector-based neural network configured to determine geometric information based on the boundary.

18. The non-transitory computer readable medium of claim 15, the operations comprising generating the at least one force diagram using graphic statics and the internal network of the natural structure.

19. The non-transitory computer readable medium of claim 18, the operations comprising generating a form diagram that represents the form of the internal network of the natural structure.

20. The non-transitory computer readable medium of claim 19, the operations comprising training the one or more machine-learning models using the force diagram and the form diagram.
